(19) United States
(12) Patent Application Publication
(10) Pub. No.: US 2026/0002054 A1
(43) Pub. Date: Jan. 1, 2026

(54) PRESSURE-SENSITIVE ADHESIVE COMPOSITION AND PRESSURE-SENSITIVE ADHESIVE SHEET

(71) Applicant: Resonac Corporation, Tokyo (JP)

(72) Inventors: Koki MARUNO, Tokyo (JP); Kazuhiro SASAKI, Tokyo (JP); Koji NAODA, Tokyo (JP); Yuya IMAI, Tokyo (JP); Kokin NAKAJIN, Tokyo (JP)

(73) Assignee: Resonac Corporation, Tokyo (JP)

(21) Appl. No.: 18/877,000

(22) PCT Filed: Jun. 14, 2024
(86) PCT No.: PCT/JP2024/021609

§ 371 Date: Dec. 19, 2024

(30) Foreign Application Priority Data
Aug. 29, 2023 (JP) 2023-139051

(51) Int. Cl. C09J 7/38; H01L 21/683

(52) U.S. Cl. CPC C09J 7/387; H01L 21/6836; C09J 2203/326; C09J 2301/208; C09J 2301/304; C09J 2301/414; C09J 2301/416

(57) ABSTRACT

A pressure-sensitive adhesive composition includes: a (meth)acrylic resin, photopolymerization initiator, and crosslinking agent, wherein the (meth)acrylic resin is a diblock copolymer of an X block and a Y block at a molar ratio from 40:60 to 95:5; the X block includes: structural unit (M-1) having a hydroxy, and structural unit (M-2) having an ethylenically unsaturated group; the Y block includes: structural unit (M-3) derived from ethylenically unsaturated compound (m-3) having an SP value of 20 (J/cm³)^{1/2} or less; at least one of structural units (M-1) to (M-3) is derived from a (meth)acryloyloxy group; a total amount of structural units (M-1) and (M-2) included in the X block is 18 to 95 mol % relative to all structural units in the X block; and a total amount of structural units (M-1) and (M-2) included in the Y block is 0 to 17 mol % relative to all structural units in the Y block.

### TECHNICAL FIELD

The present disclosure relates to a pressure-sensitive adhesive composition containing a (meth)acrylic resin. The present disclosure also relates to a pressure-sensitive adhesive sheet, a dicing tape, and a dicing/die bonding integrated film, each of which includes a cured product of the pressure-sensitive adhesive composition as a pressure-sensitive adhesive layer.

### BACKGROUND ART

In the related art, blade dicing has been used as a main method for producing a semiconductor chip to be laminated from a semiconductor wafer made of silicon (Si), gallium arsenide (GaAs), or the like. In this method, the semiconductor wafer is subjected to a step of forming a circuit on a front surface thereof and a step of polishing a rear surface thereof, then attached to a dicing tape, and cut and separated (diced) into fine semiconductor chips by a high-speed rotating blade in a dicing step. The semiconductor wafer after the dicing step is subjected to a cleaning step and is then subjected to a pickup step of picking up the semiconductor chips. In this pickup step, first, a pressure-sensitive adhesive layer of the dicing tape is irradiated with energy rays, such as ultraviolet rays to set the pressure-sensitive adhesive layer, thereby reducing the pressure-sensitive adhesive strength. Thereafter, the dicing tape is expanded and pushed up with a pin from its back surface to pick up the semiconductor chips by vacuum suction.

In the case of blade dicing, dicing is performed in a state in which cutting water is always supplied to a blade in order to cool the blade that generates heat in association with cutting and to remove cutting debris. When the cutting water enters between the dicing tape and the semiconductor wafer, the pressure-sensitive adhesive strength is significantly reduced. Thus, the dicing tape is required to have excellent water resistance.

As a dicing tape having excellent water resistance, for example, Patent Literature 1 (JP 2012-216841 A) proposes a dicing tape in which a pressure-sensitive adhesive layer obtained by adding polypropylene oxide having a specific number average molecular weight to an acrylic polymer having a radiation-polymerizable carbon-carbon double bond in the molecule and a photopolymerization initiator is formed on a base material resin film.

### CITATION LIST

### Patent Literature

PTL 1: JP 2012-216841 A

### SUMMARY OF INVENTION

### Technical Problem

As the dicing tape used in the dicing step, a tape obtained by applying a pressure-sensitive adhesive, such as an acrylic pressure-sensitive adhesive onto a resin film base material to form a pressure-sensitive adhesive layer is mainly used. The dicing tape supports the semiconductor wafer to prevent the cut semiconductor chips from scattering at the time of dicing. In recent years, miniaturization of semiconductor chips has progressed, and an area in which a dicing tape supports one semiconductor chip has become smaller. Therefore, the dicing tape is required to have an improved pressure-sensitive adhesive strength. In addition, with reduction in size of semiconductor chips, a higher level of water resistance is also required. However, the pressure-sensitive adhesive strength of the dicing tape proposed in Patent Literature 1 is low and is insufficient for supporting fine chips.

The present disclosure provides a pressure-sensitive adhesive composition that provides a pressure-sensitive adhesive sheet having excellent water resistance and sufficient pressure-sensitive adhesive strength to an adherend, and having excellent releasability after UV irradiation. Further, the present disclosure provides a pressure-sensitive adhesive sheet, a dicing tape, and a dicing/die bonding integrated film, each of which includes a cured product of the pressure-sensitive adhesive composition as a pressure-sensitive adhesive layer. More specifically, the present disclosure provides a dicing tape and a dicing/die bonding integrated film that have excellent water resistance and good dicing properties, and have excellent pickup properties after UV irradiation.

### Solution to Problem

The content of the present disclosure includes the following aspects.

[1]

A pressure-sensitive adhesive composition comprising:
a (meth)acrylic resin (A);
a photopolymerization initiator (B); and
a crosslinking agent (C), wherein
the (meth)acrylic resin (A) is a diblock copolymer composed of an X block and a Y block;
a structural unit ratio (molar ratio) between the X block and the Y block is from 40:60 to 95:5;
the X block includes:
a structural unit (M-1) having a hydroxy group, and
a structural unit (M-2) having an ethylenically unsaturated group;
the Y block includes:
a structural unit (M-3) derived from an ethylenically unsaturated compound (m-3) having an SP value of 20 (J/cm³)^{1/2} or less, and
optionally, one or more structural units selected from the group consisting of a structural unit (M-1) having a hydroxy group and a structural unit (M-2) having an ethylenically unsaturated group;
at least one of the structural unit (M-1), the structural unit (M-2), and the structural unit (M-3) has a structure derived from a (meth)acryloyloxy group;
a total amount of the structural unit (M-1) having a hydroxy group and the structural unit (M-2) having an ethylenically unsaturated group included in the X block is from 18 to 95 mol % relative to 100 mol % of a total of structural units in the X block; and
a total amount of the structural unit (M-1) having a hydroxy group and the structural unit (M-2) having an ethylenically unsaturated group included in the Y block is from 0 to 17 mol % relative to 100 mol % of a total of structural units in the Y block.
   [2]

The pressure-sensitive adhesive composition according to aspect [1], wherein an amount of the structural unit (M-2) having an ethylenically unsaturated group included in the X block is from 1 to 60 mol % relative to 100 mol % of the total of structural units in the X block.

[3]

The pressure-sensitive adhesive composition according to aspect [1] or [2], wherein an amount of the structural unit (M-1) having a hydroxy group included in the X block is from 0.1 to 35 mol % relative to 100 mol % of the total of structural units in the X block.

[4]

The pressure-sensitive adhesive composition according to any of aspects [1] to [3], wherein the structural unit (M-2) having an ethylenically unsaturated group included in the X block is a structural unit in which an isocyanato group-containing ethylenically unsaturated compound (a) is added to a hydroxy group of a structural unit derived from an ethylenically unsaturated compound (m-1) having a hydroxy group.

[5]

The pressure-sensitive adhesive composition according to any of aspects [1] to [4], wherein an amount of the structural unit (M-3) derived from the ethylenically unsaturated compound (m-3) having an SP value of 20 (J/cm³)^{1/2} or less included in the Y block is 70 mol % or more relative to 100 mol % of the total of structural units in the Y block.

[6]

The pressure-sensitive adhesive composition according to any of aspects [1] to [5], wherein the structural unit (M-3) derived from the ethylenically unsaturated compound (m-3) having an SP value of 20 (J/cm³)^{1/2} or less included in the Y block is a structural unit derived from a monomer selected from the group consisting of a linear or branched alkyl (meth)acrylate having an alkyl group with from 6 to 30 carbon atoms, an alicyclic skeleton-containing (meth)acrylate, and styrene.

[7]

The pressure-sensitive adhesive composition according to any of aspects [1] to [6], wherein the Y block includes a structural unit derived from styrene.

[8]

The pressure-sensitive adhesive composition according to any of aspects [1] to [7], wherein the X block further includes a structural unit derived from a linear or branched alkyl (meth)acrylate having an alkyl group with from 1 to 6 carbon atoms.

[9]

The pressure-sensitive adhesive composition according to any of aspects [1] to [8], wherein the (meth)acrylic resin (A) has a weight average molecular weight of from 1×10⁴ to 200×10⁴.

[10]

The pressure-sensitive adhesive composition according to any of aspects [1] to [9], wherein the (meth)acrylic resin (A) has an ethylenically unsaturated group equivalent of from 100 to 5000 g/mol.

[11]

The pressure-sensitive adhesive composition according to any of aspects [1] to [10], wherein the (meth)acrylic resin (A) has a hydroxyl value of from 0.01 to 50 mgKOH/g.

[12]

A pressure-sensitive adhesive sheet including:
a base material layer; and
a pressure-sensitive adhesive layer composed of a thermally cured product or photothermally cured product of the pressure-sensitive adhesive composition described in any one of aspects [1] to [11].
   [13]

A dicing tape including:
a base material layer; and
a pressure-sensitive adhesive layer composed of a thermally cured product or photothermally cured product of the pressure-sensitive adhesive composition described in any one of aspects [1] to [11].
   [14]

A dicing/die bonding integrated film including:
a base material layer;
a pressure-sensitive adhesive layer composed of a thermally cured product or photothermally cured product of the pressure-sensitive adhesive composition described in any one of aspects [1] to [11]; and
an adhesive layer in this order.

### Advantageous Effects of Invention

According to the present disclosure, it is possible to provide a pressure-sensitive adhesive composition that provides a pressure-sensitive adhesive sheet having high pressure-sensitive adhesive strength and excellent water resistance, and having significantly reduced pressure-sensitive adhesive strength upon ultraviolet irradiation. According to the present disclosure, it is possible to provide a pressure-sensitive adhesive sheet, a dicing tape, and a dicing/die bonding integrated film, each of which includes a cured product of the pressure-sensitive adhesive composition as a pressure-sensitive adhesive layer. According to the present disclosure, there is provided a pressure-sensitive adhesive sheet having excellent water resistance and sufficient pressure-sensitive adhesive strength to an adherend, and having excellent releasability after UV irradiation. In addition, there are provided a dicing tape and a dicing/die bonding integrated film capable of suppressing chip fly-off of a fine semiconductor chip and easily picking up the semiconductor chip after ultraviolet irradiation.

### DESCRIPTION OF EMBODIMENTS

Hereinafter, embodiments of the present invention will be described in detail. However, the present invention is not limited to the embodiments described below.

In the present specification, when “to” is used for a numerical range, the numerical values at both ends are an upper limit value and a lower limit value, respectively, and are included in the numerical range. When a plurality of upper limit values or lower limit values are described, a numerical range can be created from all combinations of the upper limit values and the lower limit values. Similarly, when a plurality of numerical ranges are described, the upper limit value and the lower limit value can be individually selected and combined from the numerical ranges to create separate numerical ranges.

In the present disclosure, the term “(meth)acrylic” means “acrylic” or “methacrylic”, the term “(meth)acrylate” means “acrylate” or “methacrylate”, and the term “(meth)acryloyloxy” means “acryloyloxy” or “methacryloyloxy”.

In the present specification, the “structural unit” means a unit derived from a polymerizable compound used as a monomer or a unit obtained by further modifying a unit derived from a polymerizable compound used as a monomer.

In the present specification, the “photocrosslinkable pressure-sensitive adhesive” means a thermally cured product of a pressure-sensitive adhesive composition, which has photocrosslinkability in a state of the thermally cured product. The photocrosslinkable pressure-sensitive adhesive can be crosslinked by ultraviolet irradiation.

In the present specification, the “photothermally cured product” means a product obtained by crosslinking the photocrosslinkable pressure-sensitive adhesive by ultraviolet irradiation.

In the present specification, the “weight-average molecular weight (Mw)” and “number-average molecular weight (Mn)” are a value measured using gel permeation chromatography (GPC) at normal temperature (23° C.) under the following conditions, and determined using a standard polystyrene calibration curve.
Apparatus: Shodex (trademark) GPC-101 (Resonac Corporation)
Column: Shodex (trademark) LF-804 (Resonac Corporation)
Column temperature: 40° C.
Sample: 0.2% by mass solution of a sample in tetrahydrofuran
Flow rate: 1 mL/min
Eluent: tetrahydrofuran
Detector: Shodex (trademark) RI-71S (Resonac Corporation)

In the present specification, the “glass transition temperature (Tg)” is a temperature at which heat absorption starts due to glass transition observed when 10 mg of a sample is taken and subjected to differential scanning calorimetry using a differential scanning calorimeter (DSC) while changing the temperature of the sample from −100° C. to 200° C. at a rate of temperature increase of 10° C./min. If two or more heat absorption start temperatures are observed, the Tg is a simple average of the two or more heat absorption start temperatures.

### [Pressure-sensitive Adhesive Composition]

The pressure-sensitive adhesive composition contains a (meth)acrylic resin (A), a photopolymerization initiator (B), a crosslinking agent (C), and an additional component to be added as necessary. The pressure-sensitive adhesive composition containing the (meth)acrylic resin (A) is suitably used in a removable pressure-sensitive adhesive sheet, particularly in a dicing tape and a dicing/die bonding integrated film.

### < (Meth)acrylic Resin (A)>

The (meth)acrylic resin (A) is a diblock copolymer composed of an X block and a Y block. The (meth)acrylic resin (A) has at least one structure derived from a (meth)acryloyloxy group. The structural unit ratio (molar ratio) between the X block and the Y block is from 40:60 to 95:5. When a raw material monomer group containing a monomer contributing to pressure-sensitive adhesiveness and a monomer contributing to water resistance is subjected to free radical polymerization, the properties of the monomers are averaged in the resulting copolymer, and it is difficult to make full use of the properties of the respective monomer species. To make further use of the properties of the respective monomer species, the present inventors have studied a copolymer having a plurality of types of blocks including specific structural units. As a result, they have found that a diblock copolymer composed of two types of blocks including specific structural units gives a pressure-sensitive adhesive composition having excellent water resistance and pressure-sensitive adhesive strength.

The structural unit ratio of the X block is 40 mol % or more, preferably 50 mol % or more, and more preferably 55 mol % or more, with respect to all the structural units of the (meth)acrylic resin (A). The structural unit ratio of the X block is 95 mol % or less, preferably 90 mol % or less, and more preferably 85 mol % or less, with respect to all the structural units of the (meth)acrylic resin (A). Any combination of these lower and upper limits is acceptable. When the structural unit ratio of the X block is 40 mol % or more, sufficient pressure-sensitive adhesive strength of the pressure-sensitive adhesive layer to an adherend can be obtained. Therefore, when it is used as a dicing tape or a dicing/die bonding integrated film, the dicing properties are sufficient. When the structural unit ratio of the X block is 95 mol % or less, sufficient water resistance of the pressure-sensitive adhesive layer to an adherend can be obtained. Therefore, when it is used as a dicing tape or a dicing/die bonding integrated film, the pressure-sensitive adhesive strength is sufficient in a step using water, such as cutting water.

The structural unit ratio of the Y block is 5 mol % or more, preferably 10 mol % or more, and more preferably 15 mol % or more, with respect to all the structural units of the (meth)acrylic resin (A). The structural unit ratio of the Y block is 60 mol % or less, preferably 50 mol % or less, and more preferably 45 mol % or less, with respect to all the structural units of the (meth)acrylic resin (A). Any combination of these lower and upper limits is acceptable. When the structural unit ratio of the Y block is 5 mol % or more, sufficient water resistance of the pressure-sensitive adhesive layer to an adherend can be obtained. Therefore, when it is used as a dicing tape or a dicing/die bonding integrated film, the pressure-sensitive adhesive strength is sufficient in a step using water, such as cutting water. When the structural unit ratio of the Y block is 60 mol % or less, sufficient pressure-sensitive adhesive strength of the pressure-sensitive adhesive layer to an adherend can be obtained. Therefore, when it is used as a dicing tape or a dicing/die bonding integrated film, the dicing properties are sufficient.

The X block includes a structural unit (M-1) having a hydroxy group (also referred to as structural unit (M-1)) and a structural unit (M-2) having an ethylenically unsaturated group (also referred to as structural unit (M-2)). The X block further includes an additional structural unit (M-4) other than the structural unit (M-1) and the structural unit (M-2) (also referred to as structural unit (M-4)). The total amount of the structural unit (M-1) having a hydroxy group and the structural unit (M-2) having an ethylenically unsaturated group included in the X block is 18 mol % or more, preferably 19 mol % or more, and more preferably 20 mol % or more, relative to 100 mol % of the total of structural units in the X block. The total amount of the structural unit (M-1) having a hydroxy group and the structural unit (M-2) having an ethylenically unsaturated group included in the X block is 95 mol % or less, preferably 60 mol % or less, and more preferably 40 mol % or less, relative to 100 mol % of the total of structural units in the X block. Any combination of these lower and upper limits is acceptable.

The Y block includes a structural unit (M-3) derived from an ethylenically unsaturated compound (m-3) having an SP value of 20 (J/cm³)^{1/2} or less (also referred to as compound (m-3)) and having neither an ethylenically unsaturated group nor a hydroxy group (also referred to as structural unit (M-3)). The Y block may include an additional structural unit other than the structural unit (M-3), which is selected from the group consisting of a structural unit (M-1) having a hydroxy group, a structural unit (M-2) having an ethylenically unsaturated group, and an additional structural unit (M-5) other than the structural units (M-1) to (M-3) (also referred to as structural unit (M-5)), as necessary. The total amount of the structural unit (M-1) having a hydroxy group and the structural unit (M-2) having an ethylenically unsaturated group included in the Y block is 0 mol % or more, may be 3 mol % or more, or may be 5 mol % or more, relative to 100 mol % of the total of structural units in the Y block. The total amount of the structural unit (M-1) having a hydroxy group and the structural unit (M-2) having an ethylenically unsaturated group included in the Y block is 17 mol % or less, preferably 15 mol % or less, and more preferably 10 mol % or less, relative to 100 mol % of the total of structural units in the Y block. Any combination of these lower and upper limits is acceptable.

When the pressure-sensitive adhesive composition contains the (meth)acrylic resin (A), sufficient pressure-sensitive adhesive strength to an adherend is obtained mainly due to the contribution of the X block, and excellent releasability from the adherend is obtained after UV irradiation. When the pressure-sensitive adhesive composition contains the (meth)acrylic resin (A), a pressure-sensitive adhesive sheet having good water resistance is obtained mainly due to the contribution of the Y block. For this reason, the dicing tape and the dicing/die bonding integrated film using the pressure-sensitive adhesive composition containing the (meth)acrylic resin (A) in the pressure-sensitive adhesive layer have excellent water resistance even in a step using water, such as cutting water, have good dicing properties, and have excellent pickup properties of individualized semiconductor chips after UV irradiation.

A weight average molecular weight (Mw) of the (meth)acrylic resin (A) is preferably 1× 10⁴ or more, more preferably 3×10⁴ or more, and still more preferably 10×10⁴ or more. The weight average molecular weight (Mw) of the (meth)acrylic resin (A) is preferably 200×10⁴ or less, more preferably 150×10⁴ or less, and still more preferably 100×10⁴ or less. Any combination of these lower and upper limits is acceptable. When the weight average molecular weight (Mw) is 1×10⁴ or more, the pressure-sensitive adhesive strength of the pressure-sensitive adhesive sheet obtained by setting the pressure-sensitive adhesive composition is good, and in the case where the pressure-sensitive adhesive sheet is used as a dicing tape or a dicing/die bonding integrated film, the dicing properties are good. When the weight average molecular weight (Mw) is 200×10⁴ or less, sufficient releasability of the pressure-sensitive adhesive layer after UV irradiation is obtained, and in the case where the pressure-sensitive adhesive sheet is used as a dicing tape or a dicing/die bonding integrated film, good pickup properties are obtained. Furthermore, sufficient strength of the pressure-sensitive adhesive layer can be obtained, and contamination of an adherend when the pressure-sensitive adhesive sheet is peeled off can be prevented. In addition, a viscosity of the pressure-sensitive adhesive composition can be controlled within an appropriate range, and workability when the pressure-sensitive adhesive composition is applied to a base material to prepare a pressure-sensitive adhesive sheet can be ensured, and a uniform film thickness can be obtained.

A molecular weight distribution (Mw/Mn) of the (meth)acrylic resin (A) may be 1.1 or more, 1.3 or more, or 1.5 or more. The molecular weight distribution (Mw/Mn) of the (meth)acrylic resin (A) is preferably 5.0 or less, more preferably 4.5 or less, and still more preferably 4.0 or less. Any combination of these lower and upper limits is acceptable. When the molecular weight distribution is 1.1 or more, the production conditions can be easily controlled. When the molecular weight distribution is 5.0 or less, a pressure-sensitive adhesive composition having higher effects can be obtained as compared with a case where the composition is synthesized by free radical polymerization without controlling the molecular weight distribution. That is, narrowing of the molecular weight distribution makes it possible to reduce the influence of the (meth)acrylic resin (A) in a low molecular weight range on the dicing properties, pickup properties, and adherend contamination of the pressure-sensitive adhesive sheet, and on the other hand, to reduce the influence of the (meth)acrylic resin (A) in a high molecular weight range on the viscosity control of the pressure-sensitive adhesive composition, and to stably obtain the performance of the pressure-sensitive adhesive sheet.

An ethylenically unsaturated group equivalent of the (meth)acrylic resin (A) is preferably 100 g/mol or more, more preferably 250 g/mol or more, and still more preferably 500 g/mol or more. The ethylenically unsaturated group equivalent of the (meth)acrylic resin (A) is preferably 5000 g/mol or less, more preferably 3000 g/mol or less, and still more preferably 2000 g/mol or less. Any combination of these lower and upper limits is acceptable. When the ethylenically unsaturated group equivalent of the (meth)acrylic resin (A) is 100 g/mol or more, the compatibility with general organic solvents is improved. When the ethylenically unsaturated group equivalent of the (meth)acrylic resin (A) is 5000 g/mol or less, sufficient releasability of the pressure-sensitive adhesive layer after UV irradiation is obtained, and in the case where the pressure-sensitive adhesive sheet is used as a dicing tape or a dicing/die bonding integrated film, good pickup properties are obtained.

In the present specification, the ethylenically unsaturated group equivalent of the (meth)acrylic resin (A) is a mass of the (meth)acrylic resin (A) per mole of an ethylenically unsaturated bond. The ethylenically unsaturated group equivalent of the (meth)acrylic resin (A) in an embodiment is a calculated value calculated from charged amounts on the assumption that 100% of raw materials used in the production of the (meth)acrylic resin (A) are reacted. The ethylenically unsaturated group equivalent of the (meth)acrylic resin (A) may be calculated from an amount of halogen bonded to the (meth)acrylic resin (A). The amount of halogen bonded to the (meth)acrylic resin (A) can be evaluated in accordance with JIS K 0070:1992.

A glass transition temperature (Tg) of the (meth)acrylic resin (A) is preferably from −80° C. to 0° C., more preferably from −70° C. to −10° C., and still more preferably from −65° C. to −20° C. When the glass transition temperature is −80° C. or higher, the pickup properties are good. When the glass transition temperature is 0° C. or lower, the adhesiveness before UV irradiation is good.

A hydroxyl value of the (meth)acrylic resin (A) is preferably 0.01 mgKOH/g or more, more preferably 2.5 mgKOH/g or more, and still more preferably 5 mgKOH/g or more. The hydroxyl value of the (meth)acrylic resin (A) is preferably 50 mgKOH/g or less, more preferably 30 mgKOH/g or less, and still more preferably 15 mgKOH/g or less. Any combination of these lower and upper limits is acceptable. When the hydroxyl value of the (meth)acrylic resin (A) is 0.01 mgKOH/g or more, the resin can be sufficiently thermally cured by a crosslinking reaction due to heating, and thus the obtained pressure-sensitive adhesive sheet has good pressure-sensitive adhesive strength. Therefore, when the pressure-sensitive adhesive sheet is used as a dicing tape or a dicing/die bonding integrated film, the dicing properties are good. Furthermore, sufficient strength of the pressure-sensitive adhesive layer can be obtained, and contamination of an adherend when the pressure-sensitive adhesive sheet is peeled off can be prevented. When the hydroxyl value of the (meth)acrylic resin (A) is 50 mgKOH/g or less, the amount of hydroxy groups contained in the pressure-sensitive adhesive layer after thermal curing is sufficiently reduced, and thus the water resistance of the obtained pressure-sensitive adhesive sheet is good. Therefore, when the pressure-sensitive adhesive sheet is used as a dicing tape or a dicing/die bonding integrated film, the pressure-sensitive adhesive sheet has excellent water resistance even in a step using water, such as cutting water, and has good dicing properties.

In the present specification, the hydroxyl value of the (meth)acrylic resin (A) is a value measured using a mixed indicator of bromothymol blue and phenol red in accordance with JIS K0070:1992. The hydroxyl value of a resin means a mass (mg) of potassium hydroxide required to neutralize acetic acid bonded to the hydroxy group when 1 g of the resin is acetylated.

### (X Block of (Meth)acrylic Resin (A))

The X block of the (meth)acrylic resin (A) includes a structural unit (M-1) having a hydroxy group and a structural unit (M-2) having an ethylenically unsaturated group. The X block further includes an additional structural unit (M-4) other than the structural unit (M-1) and the structural unit (M-2).

### <<Structural Unit (M-1) Having Hydroxy Group>>

The structural unit (M-1) is a structural unit which does not have an ethylenically unsaturated group but has a hydroxy group. The structural unit (M-1) is preferably a structural unit derived from a compound having a hydroxy group and a (meth)acryloyloxy group. When the (meth)acrylic resin (A) includes the structural unit (M-1), a pressure-sensitive adhesive sheet having sufficient pressure-sensitive adhesive strength can be obtained. In addition, crosslinking points with the crosslinking agent (C) described below can be ensured, and the strength of the pressure-sensitive adhesive layer can be improved. The structural unit (M-1) may be used alone or in combination of two or more thereof.

The content of the structural unit (M-1) in the X block is preferably 0.1 mol % or more, more preferably 1 mol % or more, and still more preferably 1.5 mol % or more, relative to 100 mol % of the total of the structural units in the X block of the (meth)acrylic resin (A). The content of the structural unit (M-1) in the X block is preferably 35 mol % or less, more preferably 20 mol % or less, and still more preferably 10 mol % or less, relative to 100 mol % of the total of the structural units in the X block of the (meth)acrylic resin (A). Any combination of these lower and upper limits is acceptable. When the content of the structural unit (M-1) in the X block is 0.1 mol % or more, the resin can be sufficiently thermally cured by a crosslinking reaction due to heating. In addition, the pressure-sensitive adhesive strength of the obtained adhesive sheet is good, and when the pressure-sensitive adhesive sheet is used as a dicing tape or a dicing/die bonding integrated film, the dicing properties are good. Furthermore, sufficient strength of the pressure-sensitive adhesive layer can be obtained, and contamination of an adherend when the pressure-sensitive adhesive sheet is peeled off can be prevented. When the content of the structural unit (M-1) in the X block is 35 mol % or less, the amount of the hydroxy group contained in the pressure-sensitive adhesive layer after thermal curing is sufficiently reduced, and thus the obtained pressure-sensitive adhesive sheet has good water resistance. Therefore, when the pressure-sensitive adhesive sheet is used as a dicing tape or a dicing/die bonding integrated film, the pressure-sensitive adhesive sheet has excellent water resistance even in a step using water, such as cutting water, and has good dicing properties.

The structural unit (M-1) is a structural unit derived from an ethylenically unsaturated compound (m-1) having a hydroxy group (also referred to as compound (m-1)). The ethylenically unsaturated compound (m-1) having a hydroxy group is not particularly limited as long as it is a compound having a hydroxy group and one ethylenically unsaturated group. Specific examples of the compound include hydroxyalkyl (meth)acrylates, such as 2-hydroxyethyl (meth)acrylate, 3-hydroxypropyl (meth)acrylate, 2-hydroxybutyl (meth)acrylate, 2,3-dihydroxypropyl (meth)acrylate and 4-hydroxybutyl (meth)acrylate; (meth)acrylates having an aromatic ring and a hydroxy group, such as hydroxyphenyl (meth)acrylate and 2-hydroxy-3-phenoxypropyl (meth)acrylate; and hydroxystyrene. Among these, hydroxyalkyl (meth)acrylates are preferable, hydroxyalkyl (meth)acrylates having a hydroxyalkyl group with from 1 to 6 carbon atoms are more preferable, hydroxyalkyl (meth)acrylates having a hydroxy group at a terminal of a linear alkyl group are still more preferable, and 2-hydroxyethyl (meth)acrylate, 3-hydroxypropyl (meth)acrylate, and 4-hydroxybutyl (meth)acrylate are particularly preferable, from the viewpoint of curability in the case of combining with the crosslinking agent (C) described later.

### <<Structural Unit (M-2) Having Ethylenically Unsaturated Group>>

The structural unit (M-2) is a structural unit having an ethylenically unsaturated group. The structural unit (M-2) is preferably a structural unit derived from a (meth)acrylate (m-2) having an ethylenically unsaturated group other than a (meth)acryloyloxy group described below, or a structural unit derived from a compound having a (meth)acryloyloxy group but not having an ethylenically unsaturated group other than the (meth)acryloyloxy group. When the (meth)acrylic resin (A) includes the structural unit (M-2), a pressure-sensitive adhesive sheet including a pressure-sensitive adhesive layer containing the (meth)acrylic resin (A) can be easily peeled off from an adherend by reducing the pressure-sensitive adhesive strength by UV irradiation after attaching the pressure-sensitive adhesive sheet to the adherend. When the pressure-sensitive adhesive sheet is used as a dicing tape or a dicing/die bonding integrated film, the dicing properties are good, and excellent pickup properties are obtained after UV irradiation. The structural unit (M-2) may be used alone or in combination of two or more thereof.

The content of the structural unit (M-2) in the X block is preferably 1 mol % or more, more preferably 8 mol % or more, and still more preferably 15 mol % or more, relative to 100 mol % of the total of the structural units in the X block of the (meth)acrylic resin (A). The content of the structural unit (M-2) in the X block is preferably 60 mol % or less, more preferably 40 mol % or less, and still more preferably 30 mol % or less, relative to 100 mol % of the total of the structural units in the X block of the (meth)acrylic resin (A). Any combination of these lower and upper limits is acceptable. When the content of the structural unit (M-2) in the X block is 1 mol % or more, sufficient releasability is obtained after ultraviolet irradiation on the pressure-sensitive adhesive sheet, and in the case where the pressure-sensitive adhesive sheet is used as a dicing tape or a die bonding/die bonding integrated film, good pickup properties are obtained. When the content of the structural unit (M-2) in the X block is 60 mol % or less, the compatibility with general organic solvents is improved.

In an embodiment, the structural unit (M-2) is a structural unit derived from a (meth)acrylate (m-2) having an ethylenically unsaturated group other than a (meth)acryloyloxy group (also referred to as compound (m-2)). Examples of the compound (m-2) include alkenyl (meth)acrylates, such as vinyl (meth)acrylate, allyl (meth)acrylate, isopropenyl (meth)acrylate, and 2-butenyl (meth)acrylate; and unsaturated alicyclic skeleton-containing (meth)acrylates, such as dicyclopentenyloxyethyl (meth)acrylate and dicyclopentenyl (meth)acrylate. Among them, from the viewpoint of reaction control, alkenyl (meth)acrylate is preferable, allyl (meth)acrylate, isopropenyl (meth)acrylate, and 2-butenyl (meth)acrylate are more preferable, and isopropenyl (meth)acrylate is still more preferable.

In an embodiment, the structural unit (M-2) is a structural unit in which the isocyanato group of an isocyanato group-containing ethylenically unsaturated compound (a) is added to a hydroxy group of a structural unit derived from an ethylenically unsaturated compound (m-1) having a hydroxy group. The isocyanato group-containing ethylenically unsaturated compound (a) is not particularly limited, specifically, as long as it is a compound having no hydroxy group and having one isocyanato group and an ethylenically unsaturated group. Specific examples of the compound include (meth)acryloyloxyalkyl isocyanates, such as 2-isocyanatoethyl (meth)acrylate, 2-isocyanatopropyl (meth)acrylate, 3-isocyanatopropyl (meth)acrylate, 2-isocyanato-1-methylethyl (meth)acrylate, 2-isocyanato-1,1-dimethylethyl (meth)acrylate and 4-isocyanatocyclohexyl (meth)acrylate; 2-(2-isocyanatoethyloxy)ethyl (meth)acrylate; and 1,1-(bis(meth)acryloyloxymethyl)ethyl isocyanate. Among them, from the viewpoint of ease of synthesis of the (meth)acrylic resin (A), (meth)acryloyloxyalkyl isocyanate is preferable, and 2-(meth)acryloyloxyethyl isocyanate is more preferable.

When the structural unit (M-2) is introduced by adding the isocyanato group-containing ethylenically unsaturated compound (a) to a part of the hydroxy group of the structural unit derived from the ethylenically unsaturated compound (m-1) having a hydroxy group contained in a (meth)acrylic copolymer, an addition rate of the isocyanato group-containing ethylenically unsaturated compound (a) to the number of moles of the hydroxy group is preferably 40 mol % or more, more preferably 60 mol % or more, and still more preferably 80 mol % or more. The addition rate of the isocyanato group-containing ethylenically unsaturated compound (a) is preferably 99 mol % or less, more preferably 98 mol % or less, and still more preferably 95 mol % or less. Any combination of these lower and upper limits is acceptable. When the addition rate of the isocyanato group-containing ethylenically unsaturated compound (a) is 40 mol % or more, sufficient releasability is obtained after ultraviolet irradiation on the pressure-sensitive adhesive sheet, and in the case where the pressure-sensitive adhesive sheet is used as a dicing tape or a dicing/die bonding integrated film, good pickup properties are obtained. When the addition rate of the isocyanato group-containing ethylenically unsaturated compound (a) is 99 mol % or less, the resin can be sufficiently thermally cured by a crosslinking reaction due to heating. In addition, the pressure-sensitive adhesive strength of the obtained pressure-sensitive adhesive sheet is good. Therefore, when the pressure-sensitive adhesive sheet is used as a dicing tape or a dicing/die bonding integrated film, the dicing properties are good. Furthermore, sufficient strength of the pressure-sensitive adhesive layer can be obtained, and contamination of an adherend when the pressure-sensitive adhesive sheet is peeled off can be prevented.

### <<Additional Structural Unit>>

The X block of the (meth)acrylic resin (A) further includes an additional structural unit (M-4) other than the structural unit (M-1) and the structural unit (M-2). The structural unit (M-4) may be used alone or in combination of two or more thereof.

The content of the additional structural unit (M-4) in the X block is 5 mol % or more, preferably 25 mol % or more, and more preferably 50 mol % or more, relative to 100 mol % of the total of the structural units in the X block of the (meth)acrylic resin (A). The content of the additional structural unit (M-4) in the X block is 82 mol % or less, preferably 78 mol % or less, more preferably 75 mol % or less, and still more preferably 70 mol % or less, relative to 100 mol % of the total of the structural units in the X block of the (meth)acrylic resin (A). Any combination of these lower and upper limits is acceptable. When the content of the additional structural unit (M-4) in the X block is 5 mol % or more, the obtained pressure-sensitive adhesive sheet has good pressure-sensitive adhesive strength. Therefore, when the pressure-sensitive adhesive sheet is used as a dicing tape or a dicing/die bonding integrated film, the dicing properties are good. When the content of the additional structural unit (M-4) in the X block is 82 mol % or less, the hydroxy group and the ethylenically unsaturated group are sufficiently contained in the (meth)acrylic resin (A), and thus thermosetting property and a decrease in pressure-sensitive adhesive strength due to ultraviolet irradiation are good. Therefore, when the pressure-sensitive adhesive sheet is used as a dicing tape or a dicing/die bonding integrated film, the dicing properties and the pickup properties become good.

Examples of the compound which provides the additional structural unit (M-4) include monomers other than the compounds (m-1) and (m-2), which are copolymerizable with the compounds (m-1) and (m-2). Specific examples of the monomers include alkyl (meth)acrylates; carboxy group-containing monomers; dienes, such as butadiene and dicyclopentadiene; styrenes; unsaturated dicarboxylic acid diesters; and other vinyl compounds.

Examples of the alkyl (meth)acrylates include linear or branched alkyl (meth)acrylates, such as methyl (meth)acrylate, ethyl (meth)acrylate, n-propyl (meth)acrylate, isopropyl (meth)acrylate, tert-butyl (meth)acrylate, pentyl (meth)acrylate, neopentyl (meth)acrylate, 2-ethylhexyl (meth)acrylate, isoamyl (meth)acrylate, and dodecyl (meth)acrylate; alicyclic alkyl (meth)acrylates, such as cyclopentyl (meth)acrylate, cyclohexyl (meth)acrylate, ethylcyclohexyl (meth)acrylate, norbornyl (meth)acrylate, dicyclopentanyl (meth)acrylate, isobornyl (meth)acrylate, and adamantyl (meth)acrylate. Among them, from the viewpoint of reactivity, linear or branched alkyl (meth)acrylates having an alkyl group with from 1 to 5 carbon atoms and cyclohexyl (meth)acrylate are preferable, and it is more preferable to use at least n-butyl (meth)acrylate.

Examples of the carboxy group-containing monomers include unsaturated monobasic acids, such as (meth)acrylic acid, crotonic acid, vinylbenzoic acid, and α-haloalkyl, alkoxyl, halogen, nitro, or cyano substitution products of acrylic acid; and unsaturated dibasic acids, such as itaconic acid. Among them, (meth)acrylic acid is preferable from the viewpoint of ease of production of the pressure-sensitive adhesive layer.

Specific examples of the styrenes include styrene and α-, o-, m-, or p-alkyl derivatives of styrene.

Specific examples of the unsaturated dicarboxylic acid diesters include diethyl citraconate, diethyl maleate, diethyl fumarate, and diethyl itaconate.

Specific examples of the other vinyl compounds include norbornene (bicyclo[2.2.1]hept-2-ene), 5-methylbicyclo[2.2.1]hept-2-ene, 5-ethylbicyclo[2.2.1]hept-2-ene, tetracyclo[4.4.0.1^{2,5}.1^{7,10}]dodec-3-ene, 8-methyltetracyclo[4.4.0.1^{2,5}.1^{7,10}]dodec-3-ene, 8-ethyltetracyclo[4.4.0.1^{2,5}.1^{7,10}]dodec-3-ene, tricyclo[5.2.1.0^{2,6}]dec-8-ene, tricyclo[5.2.1.0^{2,6}]dec-3-ene, tricyclo[4.4.0.1^{2,5}]undec-3-ene, tricyclo[6.2.1.0^{1,8}]undec-9-ene, tricyclo[6.2.1.0^{1,8}]undec-4-ene, tetracyclo[4.4.0.1^{2,5}.1^{7,10}.0^{1,6}]dodec-3-ene, 8-methyltetracyclo[4.4.0.1^{2,5}.1^{7,10}.0^{1,6}]dodec-3-ene, 8-ethylidenetetracyclo[4.4.0.1^{2,5}.1^{7,12}]dodec-3-ene, 8-ethylidenetetracyclo[4.4.0.1^{2,5}.1^{7,10}.0^{1,6}]dodec-3-ene, pentacyclo[6.5.1.1^{3,6}.0^{2,7}.0^{9,13}]pentadec-4-ene, pentacyclo[7.4.0.1^{2,5}.1^{9,12}.0^{8,13}]pentadec-3-ene, (meth)acrylic acid anilide, vinylpyridine, and vinyl acetate.

Among them, from the viewpoint of reaction control, an alkyl (meth)acrylate is preferable, and a linear or branched alkyl (meth)acrylate having an alkyl group with from 1 to 5 carbon atoms is more preferable.

### <Y Block of (Meth)acrylic Resin (A)>

The Y block of the (meth)acrylic resin (A) includes the structural unit (M-3) derived from an ethylenically unsaturated compound (m-3) having an SP value of 20 (J/cm³)^{1/2} or less. The Y block may include an additional structural unit other than the structural unit (M-3), which is selected from the group consisting of a structural unit (M-1) having a hydroxy group, a structural unit (M-2) having an ethylenically unsaturated group, and an additional structural unit (M-5) other than the structural units (M-1) to (M-3), as necessary.

<<Structural Unit (M-3) Derived from Ethylenically Unsaturated Compound (m-3) Having SP Value of 20 (J/cm³)^{1/2} or Less>>

The structural unit (M-3) is a structural unit that does not have an ethylenically unsaturated group and a hydroxy group, and is derived from an ethylenically unsaturated compound (m-3) having an SP value of 20 (J/cm³)^{1/2} or less. The structural unit (M-3) is preferably a structural unit derived from a compound having a (meth)acryloyloxy group and having an SP value of 20 (J/cm³)^{1/2} or less. The structural unit (M-3) may be used alone or in combination of two or more thereof.

In the present specification, the SP value means a solubility parameter value (δTot) calculated using a program called HSPiP (Hansen Solubility Parameters in Practice). δTot represents the magnitude of the HSP vector. When the (meth)acrylic resin (A) includes the structural unit (M-3), a pressure-sensitive adhesive sheet having good water resistance can be obtained.

The content of the structural unit (M-3) in the Y block may be 50 mol % or more, 60 mol % or more, 70 mol % or more, or 80 mol % or more, relative to 100 mol % of the total of the structural units in the Y block of the (meth)acrylic resin (A). The content of the structural unit (M-3) in the Y block may be 80 mol % or less, 90 mol % or less, or 100 mol % or less, relative to 100 mol % of the total of the structural units in the Y block of the (meth)acrylic resin (A). Any combination of these lower and upper limits is acceptable. The content of the structural unit (M-3) in the Y block is preferably 100 mol % from the viewpoint of the water resistance of the pressure-sensitive adhesive composition. When the content of the structural unit (M-3) is 50 mol % or more, the hydrophobicity of the Y block of the (meth)acrylic resin (A) is good, and thus the water resistance of the resulting pressure-sensitive adhesive sheet is good. Therefore, when the pressure-sensitive adhesive sheet is used as a dicing tape or a dicing/die bonding integrated film, the pressure-sensitive adhesive sheet has excellent water resistance even in a step using water, such as cutting water, and has good dicing properties. When the content of the structural unit (M-3) is within the above range, the Tg of the Y block of the (meth)acrylic resin (A) can be adjusted to an appropriate range, and the pressure-sensitive adhesive strength can be improved.

Specific examples of the compound (m-3) that provides the structural unit (M-3) include alkyl (meth)acrylates and styrenes. Examples of the alkyl (meth)acrylate include linear or branched alkyl (meth)acrylates having an alkyl group with from 1 to 5 carbon atoms, such as methyl (meth)acrylate (18.8, 18.0) and n-butyl (meth)acrylate (19.0, 17.1); linear or branched alkyl (meth)acrylates having an alkyl group with from 6 to 30 carbon atoms, such as stearyl (meth)acrylate (16.3, 16.3) and isostearyl (meth)acrylate (16.1,16.1); and alicyclic skeleton-containing (meth)acrylates, such as cyclopentyl (meth)acrylate (18.0, 17.6), cyclohexyl (meth)acrylate (18.0, 17.7), ethylcyclohexyl (meth)acrylate (18.2, 17.6), norbornyl (meth)acrylate (18.3, 18.0), dicyclopentanyl (meth)acrylate (17.6, 17.5), isobornyl (meth)acrylate (17.1,17.0) and adamantyl (meth)acrylate (17.7, 17.5). The numerical values after the name of each compound are the SP values ((J/cm³)^{1/2}), which are described in the order of acrylate and methacrylate. Specific examples of the styrenes include styrene (18.3); and alkyl derivatives of styrene, such as α-methylstyrene (17.8), o-methylstyrene (18.3), m-methylstyrene (18.2) and p-methylstyrene (18.6). The numerical value after the name of each compound is the SP value ((J/cm³)^{1/2}). Among these, from the viewpoints of reaction control and SP value, at least one selected from the group consisting of linear or branched alkyl (meth)acrylates having an alkyl group with from 6 to 30 carbon atoms, alicyclic skeleton-containing (meth)acrylates, and styrene is preferable, at least one selected from n-butyl acrylate, cyclohexyl acrylate, isostearyl acrylate, and styrene is more preferable, at least one selected from isostearyl acrylate and styrene is still more preferable, and styrene is particularly preferable. The compound (m-3) may be used alone or in combination of two or more thereof.

### <<Structural Unit (M-5)>>

The content of the structural unit (M-5) in the Y block may be 5 mol % or more, 10 mol % or more, or 15 mol % or more, relative to 100 mol % of the total of the structural units in the Y block of the (meth)acrylic resin (A). The content of the structural unit (M-5) in the Y block is preferably 50 mol % or less, more preferably 40 mol % or less, and still more preferably 20 mol % or less, relative to 100 mol % of the total of the structural units in the Y block of the (meth)acrylic resin (A). Any combination of these lower and upper limits is acceptable. When the content of the structural unit (M-5) in the Y block is 5 mol % or more, the Tg of the Y block of the (meth)acrylic resin (A) can be adjusted to an appropriate range, and the pressure-sensitive adhesive strength can be improved. When the content of the structural unit (M-5) in the Y block is 50 mol % or less, the hydrophobicity of the Y block of the (meth)acrylic resin (A) is good, and thus the water resistance of the resulting pressure-sensitive adhesive sheet is good. Therefore, when the pressure-sensitive adhesive sheet is used as a dicing tape or a dicing/die bonding integrated film, the pressure-sensitive adhesive sheet has excellent water resistance even in a step using water, such as cutting water, and has good dicing properties. From the viewpoint of water resistance, the Y block preferably does not have the structural unit (M-5). The structural unit (M-5) may be used alone or in combination of two or more thereof.

Examples of the compound that provides the structural unit (M-5) include monomers other than the compounds (m-1) and (m-2), which are copolymerizable with the compound (m-3) and have an SP value of more than 20 (J/cm³)^{1/2}. Specific examples of the monomers include carboxy group-containing monomers; unsaturated dicarboxylic acid diesters; and other vinyl compounds.

Examples of the carboxy group-containing monomers include unsaturated monobasic acids, such as methacrylic acid, crotonic acid, and α-haloalkyl, alkoxyl, halogen, nitro, or cyano substitution products of acrylic acid; and unsaturated dibasic acids, such as itaconic acid. Among them, methacrylic acid is preferable from the viewpoint of ease of production of the pressure-sensitive adhesive layer.

Specific examples of the unsaturated dicarboxylic acid diesters include diethyl citraconate, diethyl maleate, diethyl fumarate, and diethyl itaconate.

Specific examples of the other vinyl compounds include (meth)acrylic acid anilide.

Among them, from the viewpoint of reaction control, carboxy group-containing monomers having an SP value of more than 20 (J/cm³)^{1/2} are preferable.

The (meth)acrylic resin (A) may include at least one selected from the group consisting of the structural unit (M-1) and the structural unit (M-2) in the Y block as long as the effects are not impaired. Specific examples and suitable examples of the structural units (M-1) and (M-2) included in the Y block are the same as the structural units (M-1) and (M-2) included in the X block.

When the Y block includes the structural unit (M-1), the content of the structural unit (M-1) in the Y block may be 1 mol % or more, 2 mol % or more, or 5 mol % or more, relative to 100 mol % of the total of the structural units in the Y block of the (meth)acrylic resin (A). When the Y block includes the structural unit (M-1), the content of the structural unit (M-1) in the Y block is preferably 15 mol % or less, more preferably 10 mol % or less, and still more preferably 5 mol % or less, relative to 100 mol % of the total of the structural units in the Y block of the (meth)acrylic resin (A), from the viewpoint of improving the water resistance of the pressure-sensitive adhesive sheet. Any combination of these lower and upper limits is acceptable.

When the Y block of the (meth)acrylic resin (A) includes the structural unit (M-1), the resin can be sufficiently thermally cured by a crosslinking reaction due to heating. The pressure-sensitive adhesive strength of the obtained pressure-sensitive adhesive sheet is also good, and when the adhesive sheet is used as a dicing tape or a dicing/die bonding integrated film, the dicing properties are good. Furthermore, sufficient strength of the pressure-sensitive adhesive layer can be obtained, and contamination of an adherend when the pressure-sensitive adhesive sheet is peeled off can be prevented. On the other hand, from the viewpoint of improving water resistance, the (meth)acrylic resin (A) preferably does not have the structural unit (M-1) in the Y block.

When the Y block of the (meth)acrylic resin (A) includes the structural unit (M-2), the content of the structural unit (M-2) in the Y block may be 1 mol % or more, 2 mol % or more, or 5 mol % or more, relative to 100 mol % of the total of the structural units in the Y block of the (meth)acrylic resin (A). When the Y block includes the structural unit (M-2), the content of the structural unit (M-2) in the Y block is preferably 15 mol % or less, more preferably 10 mol % or less, and still more preferably 5 mol % or less, relative to 100 mol % of the total of the structural units in the Y block of the (meth)acrylic resin (A). Any combination of these lower and upper limits is acceptable. When the Y block of the (meth)acrylic resin (A) includes the structural unit (M-2), a pressure-sensitive adhesive sheet including a pressure-sensitive adhesive layer containing the (meth)acrylic resin (A) can be easily peeled off from an adherend by reducing the pressure-sensitive adhesive strength by UV irradiation after attaching the pressure-sensitive adhesive sheet to the adherend. When it is used as a dicing tape or a dicing/die bonding integrated film, excellent pickup properties are obtained after UV irradiation. On the other hand, from the viewpoint of improving water resistance, the (meth)acrylic resin (A) preferably does not have the structural unit (M-2) in the Y block.

### <Photopolymerization Initiator (B)>

Examples of the photopolymerization initiator (B) include carbonyl-based photopolymerization initiators, such as benzophenone, benzyl, benzoin, @-bromoacetophenone, chloroacetone, acetophenone, 2,2-diethoxyacetophenone, 2,2-dimethoxy-2-phenylacetophenone, p-dimethylaminoacetophenone, p-dimethylaminopropiophenone, 2-chlorobenzophenone, 4,4′-dichlorobenzophenone, 4,4′-bisdiethylaminobenzophenone, Michler's ketone, benzoin methyl ether, benzoin isobutyl ether, benzoin-n-butyl ether, benzyl methyl ketal, 1-hydroxycyclohexyl phenyl ketone, 2-hydroxy-2-methyl-1-phenyl-propane-1-one, 1-(4-isopropylphenyl)-2-hydroxy-2-methylpropane-1-one, methyl benzoylformate, 4′-dimethylaminoacetophenone, and 2-methyl-1-[4-(methylthio)phenyl]-2-morpholinopropane-1-one.

Examples of the photopolymerization initiator (B) also include sulfide-based photopolymerization initiators, such as diphenyl disulfide, dibenzyl disulfide, tetraethylthiuram disulfide, and tetramethylammonium monosulfide; acylphosphine oxides, such as 2,4,6-trimethylbenzoyldiphenylphosphine oxide and 2,4,6-trimethylbenzoylphenylethoxyphosphine oxide; quinone-based photopolymerization initiators, such as benzoquinone and anthraquinone; sulfochloride-based photopolymerization initiators; and thioxanthone-based photopolymerization initiators, such as thioxanthone, 2-chlorothioxanthone, and 2-methylthioxanthone.

Among these photopolymerization initiators (B), from the viewpoint of solubility in the pressure-sensitive adhesive composition, carbonyl-based photopolymerization initiators and acylphosphine oxides are preferable, and at least one selected from 1-hydroxycyclohexyl phenyl ketone and 2,4,6-trimethylbenzoyldiphenylphosphine oxide is more preferably used.

The photopolymerization initiator (B) may be used alone or in combination of two or more thereof.

A content of the photopolymerization initiator (B) is preferably from 0.1 to 5.0 parts by mass, and more preferably from 0.3 to 2.0 parts by mass, per 100 parts by mass of the (meth)acrylic resin (A). When the content of the photopolymerization initiator (B) is 0.1 parts by mass or more per 100 parts by mass of the (meth)acrylic resin (A), a crosslinking density of the photocrosslinkable pressure-sensitive adhesive (i.e., a thermally cured product of the pressure-sensitive adhesive composition) can be improved at a sufficiently high setting rate during UV irradiation. Therefore, when the photocrosslinkable pressure-sensitive adhesive is used in the pressure-sensitive adhesive layer, the pressure-sensitive adhesive strength of the pressure-sensitive adhesive layer after UV irradiation can be sufficiently reduced. When the content of the photopolymerization initiator (B) is 5.0 parts by mass or less per 100 parts by mass of the (meth)acrylic resin (A), the pressure-sensitive adhesive strength before UV irradiation and water resistance of the pressure-sensitive adhesive layer can be sufficiently retained. An effect commensurate with the content of the photopolymerization initiator (B) is not exhibited when the content of the photopolymerization initiator (B) is more than 5.0 parts by mass per 100 parts by mass of the (meth)acrylic resin (A), and therefore the content is adjusted to 5.0 parts by mass or less, so that a pressure-sensitive adhesive composition can be produced economically.

### <Crosslinking Agent (C)>

The crosslinking agent (C) is a compound having no ethylenically unsaturated bond and having two or more functional groups reactive with the hydroxy group contained in the (meth)acrylic resin (A). The functional group of the crosslinking agent (C) and the hydroxy group of the (meth)acrylic resin (A) are reacted by heating to set the pressure-sensitive adhesive composition, whereby a photocrosslinkable pressure-sensitive adhesive can be obtained. When the photocrosslinkable pressure-sensitive adhesive is used in the pressure-sensitive adhesive layer, a pressure-sensitive adhesive sheet having a good balance between the pressure-sensitive adhesive strength before UV irradiation and the pressure-sensitive adhesive strength after UV irradiation can be obtained.

Examples of the functional group having reactivity with the hydroxy group, which is included in the crosslinking agent (C), include an isocyanato group, an epoxy group, a carboxy group, an acid anhydride group, and an aziridinyl group. From the viewpoint of reactivity, an isocyanato group and an epoxy group are preferable, and an isocyanato group is particularly preferable.

Examples of the crosslinking agent (C) include polyisocyanates, such as 2,4-tolylene diisocyanate, 2,6-tolylene diisocyanate, hydrogenated tolylene diisocyanate, 1,3-xylylene diisocyanate, 1,4-xylylene diisocyanate, diphenylmethane-4,4′-diisocyanate, isophorone diisocyanate, 1,3-bis(isocyanatomethyl)cyclohexane, isocyanurate forms of hexamethylene diisocyanate, tetramethylxylylene diisocyanate, 1,5-naphthalene diisocyanate, tolylene diisocyanate adducts of trimethylolpropane, xylylene diisocyanate adducts of trimethylolpropane, triphenylmethane triisocyanate and methylenebis(4-phenylmethane)triisocyanate; polyepoxy compounds, such as 1,3-bis (N,N′-diglycidylaminomethyl)cyclohexane, bisphenol A-epichlorohydrin type epoxy resin, N,N′-[1,3-phenylenebis(methylene)]bis[bis (oxirane-2-ylmethyl)amine], ethylene glycol diglycidyl ether, polyethylene glycol diglycidyl ether, glycerin diglycidyl ether, glycerin triglycidyl ether, 1,6-hexanediol diglycidyl ether, trimethylolpropane triglycidyl ether, sorbitol polyglycidyl ether, polyglycerol polyglycidyl ether, pentaerythritol polyglycidyl ether, and diglycerol polyglycidyl ether; melamine compounds, such as hexamethoxymethylmelamine, hexaethoxymethylmelamine, hexapropoxymethylmelamine, hexabutoxymethylmelamine, hexapentyloxymethylmelamine and hexahexyloxymethylmelamine; aziridinyl compounds, such as ethylene glycol-bis-[3-(2-aziridinyl) propionate], trimethylolpropane-tris[3-(2-aziridinyl) propionate], trimethylolpropane-tris[3-(1-aziridinyl) propionate], trimethylolpropane-tris[3-(2-methyl-1-aziridinyl) propionate], tetramethylolmethane-tris[3-(2-aziridinyl) propionate], pentaerythritol-tris[3-(1-aziridinyl) propionate], N,N′-diphenylmethane-4,4′-bis (1-aziridinylcarboxamide), and N,N′-hexamethylene-1,6-bis (1-aziridinecarboxamide).

Among these crosslinking agents (C), it is preferable to use at least one selected from the group consisting of polyisocyanates and polyepoxy compounds, and it is more preferable to use polyisocyanates, because they have good reactivity with the (meth)acrylic resin (A).

The crosslinking agent (C) may be used alone or in combination of two or more thereof.

A content of the crosslinking agent (C) is preferably from 0.1 to 30 parts by mass, more preferably from 0.1 to 20 parts by mass, still more preferably from 0.1 to 10 parts by mass, and even more preferably from 0.1 to 5 parts by mass, per 100 parts by mass of the (meth)acrylic resin (A). When the content of the crosslinking agent (C) is 0.1 parts by mass or more per 100 parts by mass of the (meth)acrylic resin (A), a three-dimensional crosslinked structure is sufficiently formed in the photocrosslinkable pressure-sensitive adhesive upon UV irradiation. Therefore, when the photocrosslinkable pressure-sensitive adhesive is used as the pressure-sensitive adhesive, the pressure-sensitive adhesive strength of the pressure-sensitive adhesive after UV irradiation can be made sufficiently small. When the content of the crosslinking agent (C) is 30 parts by mass or less per 100 parts by mass of the (meth)acrylic resin (A), the balance in properties between the photocrosslinkable pressure-sensitive adhesive and the cured product after UV irradiation is good, and in the case where it is used as a dicing tape or a dicing/die bonding integrated film, good pressure-sensitive adhesive strength and water resistance are exhibited. When the photocrosslinkable pressure-sensitive adhesive is used as the pressure-sensitive adhesive, the pressure-sensitive adhesive strength before UV irradiation is good.

### <Additional Component>

The pressure-sensitive adhesive composition may contain an additional component other than the (meth)acrylic resin (A), the photopolymerization initiator (B), and the crosslinking agent (C) described above, as necessary. Examples of the additional component include a tackifier, a solvent, and various additives.

### (Tackifier)

As the tackifier, a known tackifier can be used without particular limitation. Examples of the tackifier include a terpene-based tackifier resin, a phenol-based tackifier resin, a rosin-based tackifier resin, an aliphatic petroleum resin, an aromatic petroleum resin, a copolymer petroleum resin, an alicyclic petroleum resin, a xylene resin, an epoxy-based tackifier resin, a polyamide-based tackifier resin, a ketone-based tackifier resin, and an elastomer-based tackifier resin. The tackifier may be used alone or in combination of two or more thereof.

When the tackifier is used, a content thereof in the pressure-sensitive adhesive composition is preferably 30 parts by mass or less, and more preferably from 5 to 20 parts by mass, per 100 parts by mass of the (meth)acrylic resin (A).

### (Solvent)

The solvent can be used to dilute the pressure-sensitive adhesive composition for the purpose of adjusting the viscosity of the pressure-sensitive adhesive composition. For example, when the pressure-sensitive adhesive composition is applied, a solvent can be used to adjust the viscosity of the pressure-sensitive adhesive composition to an appropriate viscosity. As the solvent, the solvent used when synthesizing the (meth)acrylic resin (A) may be used as it is, or a solvent may be further added to the solvent.

Examples of the solvent that can be used include organic solvents, such as methyl ethyl ketone, methyl isobutyl ketone, acetone, ethyl acetate, propyl acetate, butyl acetate, tetrahydrofuran, dioxane, cyclohexanone, hexane, toluene, xylene, n-propanol, and isopropyl alcohol. The solvent may be used alone or in combination of two or more thereof.

### (Additives)

Examples of the additives include plasticizers, surface lubricants, leveling agents, softeners, antioxidants, antiaging agents, light stabilizers, ultraviolet absorbers, polymerization inhibitors, light stabilizers, such as a benzotriazole-based compound, phosphoric acid ester-based and other flame retardants, surfactants, and antistatic agents.

### [Method for Producing (Meth)acrylic Resin (A)]

The (meth)acrylic resin (A) can be produced, for example, by a method including step (i-1) of subjecting a raw material monomer group (m-X) constituting an X block to reversible addition-fragmentation chain transfer (RAFT) polymerization, step (i-2) of subjecting a raw material monomer group (m-Y) constituting a Y block to reversible addition-fragmentation chain transfer (RAFT) polymerization, and optionally step (ii) of introducing an ethylenically unsaturated group by adding an ethylenically unsaturated compound having a functional group, such as an isocyanato group to a part of hydroxy groups of the copolymer obtained by steps (i-1) and (i-2). The order of step (i-1) and step (i-2) for synthesizing each block is not particularly limited, but step (i-2) is preferably performed before step (i-1). Exemplary embodiments of step (i-1), step (i-2) and step (ii) are described below.

### Step (i-1)

Step (i-1) is a step of RAFT polymerizing a raw material monomer group (m-X) containing an ethylenically unsaturated compound (m-1) having a hydroxy group, optionally a (meth)acrylate (m-2) having an ethylenically unsaturated group other than a (meth)acryloyloxy group, and optionally an additional monomer other than the compounds (m-1) and (m-2) in the presence of a reversible addition-fragmentation chain transfer agent (RAFT agent). As used herein, the RAFT polymerization refers to radical polymerization carried out in the presence of a RAFT agent. The RAFT polymerization is a type of living radical polymerization. The living radical polymerization is generally known as a polymerization method by which a polymer having a small molecular weight distribution can be obtained, and specific examples thereof include atom transfer radical polymerization, organotellurium-mediated radical polymerization, and RAFT polymerization. Of these, the RAFT polymerization is preferred for pressure-sensitive adhesive applications.

The weight average molecular weight of each block obtained in steps (i-1) and (i-2) can be controlled, for example, by adjusting the amounts of the radical polymerization initiator and the RAFT agent used. By controlling the weight average molecular weight of each block, the structural unit ratio (molar ratio) between the X block and the Y block can be controlled to be in a desired range.

A reaction temperature can be appropriately set depending on the type of the radical polymerization initiator used and the like. A reaction temperature is preferably from 40 to 125° C., and more preferably from 60 to 120° C. A reaction time can be appropriately set depending on the type of the radical polymerization initiator used and the like. A reaction time is preferably from 5 to 24 hours, and more preferably from 10 to 15 hours.

Examples of polymerization method that can be used include a solution polymerization method, an emulsion polymerization method, a bulk polymerization method, a suspension polymerization method, and an alternating copolymerization method. Among these polymerization methods, in consideration of the addition reaction in step (ii), a solution polymerization method is preferably used in terms of ease of reaction.

From the viewpoint of a polymerization rate of the raw material monomer group (m-X), a total concentration of the components excluding the solvent in the solution polymerization is preferably from 30 to 90 mass %, and more preferably from 50 to 80 mass %. Since steps (i-1) and (i-2) are RAFT polymerization, the polymerization proceeds by an equilibrium reaction. Therefore, the progress of the polymerization is very mild, and the polymerization can be carried out at a high concentration.

### (Reversible Addition-Fragmentation Chain Transfer Agent (RAFT Agent))

As the RAFT agent, a known agent can be used without particular limitation as long as it is of a type in which a polymer extends in one direction from a thiocarbonylthio group as a starting point. Examples of the RAFT agent include trithiocarbonates, dithioesters, dithiocarbonates, and dithiocarbamates. When polymerization is carried out in the presence of such a RAFT agent, the polymerization proceeds while radical species undergo chain reaction between a sulfur atom in the RAFT agent and a carbon atom adjacent to the sulfur atom. Among them, trithiocarbonate is preferable from the viewpoint that the reaction speed and the reaction rate of polymerization are increased due to the magnitude of the transfer constant, and thus that the molecular weight distribution is easily narrowed. It should be noted that the bilaterally symmetric trithiocarbonate cannot be used because the polymer extends in two directions starting from the trithiocarbonate site, and thus an X—Y—X type triblock copolymer is formed when the polymerization is performed in the order of step (i-1) and step (i-2), and a Y—X—Y type triblock copolymer is formed when the polymerization is performed in the order of step (i-2) and step (i-1).

Specific examples of the RAFT agent include sulfur-based compounds (trithiocarbonate, dithioester, dithiocarbonate, and dithiocarbamate) represented by the following formula (1), formula (2), formula (3), or formula (4).

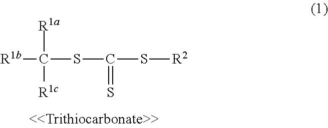

wherein R^{1a} and R^{1b} each independently represent a hydrogen atom, a hydrocarbon group, a carboxy group, or a cyano group, R^{1c} represents a cyano group; a saturated or unsaturated aliphatic hydrocarbon group, which may be substituted with a cyano group or a carboxy group; or an optionally substituted phenyl group, and R² represents a saturated or unsaturated aliphatic hydrocarbon group in which a part of hydrogen atoms may be substituted with a carboxy group; or a benzyl group in which a part of hydrogen atoms may be substituted with a substituted carbamoyl group, an alkoxycarbonyl group with from 2 to 5 carbon atoms, which may be substituted with a hydroxy group, or an alkenyloxycarbonyl group with from 3 to 5 carbon atoms, provided that (R^{1a}) (R^{1b}) (R^{1c})C and R² are different.

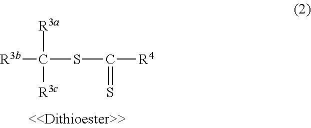

wherein R^{3a} and R^{3b} each independently represent a hydrogen atom, a hydrocarbon group, or a cyano group, R^{3c} represents a carboxy group; an acetoxymethyl group; or a hydrocarbon group, which may be substituted with a cyano group or a carboxy group, and R⁴ represents a hydrocarbon group.

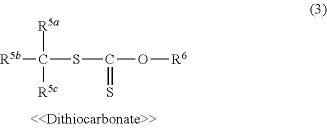

wherein R^{5a} and R^{5b} each independently represent a hydrogen atom; a hydrocarbon group; a carboxy group, which may be substituted with a saturated aliphatic hydrocarbon group having from 1 to 3 carbon atoms; or a cyano group, R^{5c} represents a hydrocarbon group, which may be substituted with an alkoxy group, and R⁶ represents a hydrocarbon group.

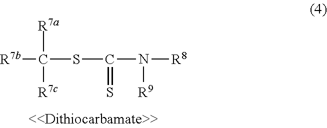

wherein R^{7a} and R^{7b} each independently represent a hydrogen atom or a hydrocarbon group, R^{7c} represents a cyano group, R⁸ and R⁹ each independently represent a hydrocarbon group, or R⁸ and R⁹ may be bonded to each other to form a pyrazole ring, which may be substituted with a saturated aliphatic hydrocarbon group having from 1 to 3 carbon atoms or a chlorine atom.

In formula (1), examples of the hydrocarbon group represented by R₁ₐ and R^{1b} include a linear, branched, or cyclic, saturated or unsaturated hydrocarbon group having from 1 to 20 carbon atoms, and among them, a linear, branched, or cyclic, saturated or unsaturated hydrocarbon group having from 1 to 12 carbon atoms is preferable. Examples of the hydrocarbon group include linear, branched or cyclic saturated aliphatic hydrocarbon groups having from 1 to 20 carbon atoms, such as a methyl group, an ethyl group, an n-propyl group, an isopropyl group, an n-butyl group, an isobutyl group, a tert-butyl group, a cyclohexyl group, an undecyl group, a dodecyl group and an octadecyl group; aryl groups having from 6 to 12 carbon atoms, such as a phenyl group; and arylalkyl groups having from 7 to 10 carbon atoms, such as a benzyl group and a phenethyl group. Examples of the saturated or unsaturated aliphatic hydrocarbon group represented by R^{1c} in formula (1) include a linear, branched, or cyclic, saturated or unsaturated aliphatic hydrocarbon group having from 1 to 20 carbon atoms, and among them, a linear, branched, or cyclic, saturated or unsaturated aliphatic hydrocarbon group having from 1 to 12 carbon atoms is preferable. Examples of the aliphatic hydrocarbon group include linear, branched or cyclic saturated aliphatic hydrocarbon groups having from 1 to 20 carbon atoms, such as a methyl group, an ethyl group, an n-propyl group, an isopropyl group, an n-butyl group, an isobutyl group, a tert-butyl group, a cyclohexyl group, an undecyl group, a dodecyl group and an octadecyl group. In formula (1), for example, from 1 to 3 hydrogen atoms in the saturated or unsaturated aliphatic hydrocarbon group represented by R^{1c} may be substituted with carboxy groups or cyano groups, and the carboxy groups may be further substituted with a saturated aliphatic hydrocarbon group having from 1 to 3 carbon atoms. In formula (1), examples of substituents of the optionally substituted phenyl groups represented by R^{1c} include substituted carbamoyl groups, alkoxycarbonyl groups with from 2 to 5 carbon atoms, which may be substituted with a hydroxy group, and alkenyloxycarbonyl groups having from 3 to 5 carbon atoms. Examples of the substituent of the substituted carbamoyl group include a saturated aliphatic hydrocarbon group with from 1 to 3 carbon atoms, which may be substituted with a hydroxy group or an acetyloxy group. Examples of the saturated or unsaturated aliphatic hydrocarbon group represented by R² in formula (1) include a linear, branched, or cyclic saturated or unsaturated aliphatic hydrocarbon group having from 1 to 20 carbon atoms, and among them, an aliphatic hydrocarbon group having from 1 to 12 carbon atoms is preferable. Examples of the aliphatic hydrocarbon group include linear, branched or cyclic saturated aliphatic hydrocarbon groups having from 1 to 20 carbon atoms, such as a methyl group, an ethyl group, an n-propyl group, an isopropyl group, an n-butyl group, an isobutyl group, a tert-butyl group, a cyclohexyl group, a dodecyl group and an octadecyl group. In formula (1), for example, from 1 to 3 hydrogen atoms in the saturated or unsaturated aliphatic hydrocarbon group represented by R² may be substituted with carboxy groups. In formula (1), examples of the substituent of the substituted carbamoyl group of the optionally substituted benzyl group represented by R² include a saturated aliphatic hydrocarbon group with from 1 to 3 carbon atoms, which may be substituted with a hydroxy group or an acetyloxy group. Among these, a compound represented by formula (1) in which R^{1a} and R^{1b} each independently represents a hydrogen atom, a hydrocarbon group having from 1 to 4 carbon atoms, a carboxy group, or a cyano group, R^{1c} is an undecyl group, a hydrocarbon group with from 1 to 4 carbon atoms, which may be substituted with a carboxy group, or an optionally substituted phenyl group, R² is a linear, branched or cyclic, saturated or unsaturated aliphatic hydrocarbon group having from 1 to 20 carbon atoms, or an optionally substituted benzyl group is preferable; and a compound represented by formula (1) in which R^{1a} and R^{1b} are each a combination of a hydrogen atom, a methyl group or an ethyl group and a cyano group or a carboxy group, or a hydrogen atom, R 1c is a methyl group, an ethyl group, an undecyl group or an optionally substituted phenyl group, R² is a linear saturated aliphatic hydrocarbon group having from 1 to 20 carbon atoms; or a benzyl group in which a part of hydrogen atoms may be substituted with a substituted carbamoyl group, an alkoxycarbonyl group with from 2 to 5 carbon atoms, which may be substituted with a hydroxy group, or an alkenyloxycarbonyl group having from 3 to 5 carbon atoms is more preferable.

Examples of the hydrocarbon groups represented by R^{3a}, R^{3b}, R^{3c}, and R⁴ in formula (2) include linear, branched, or cyclic, saturated or unsaturated hydrocarbon groups having from 1 to 20 carbon atoms, and among them, a linear, branched, or cyclic, saturated or unsaturated hydrocarbon group having from 1 to 12 carbon atoms is preferable. Examples of the hydrocarbon group include linear, branched, or cyclic saturated aliphatic hydrocarbon groups having from 1 to 20 carbon atoms, such as a methyl group, an ethyl group, an n-propyl group, an isopropyl group, an n-butyl group, an isobutyl group, a tert-butyl group, a cyclohexyl group, a dodecyl group and an octadecyl group; aryl groups having from 6 to 12 carbon atoms, such as a phenyl group; and arylalkyl groups having from 7 to 10 carbon atoms, such as a benzyl group and a phenethyl group. In formula (2), examples of the hydrocarbon group, which may be substituted with a cyano group or a carboxy group, and represented by R^{3c} include groups in which from 1 to 3 hydrogen atoms in the aforementioned hydrocarbon groups have been substituted with cyano groups or carboxy groups. Among these, a compound represented by formula (2) in which R^{3a} and R^{3b} are each independently a linear saturated hydrocarbon group having from 1 to 4 carbon atoms, R^{3c} is an aryl group, and R⁴ is an aryl group or a benzyl group is preferable, and a compound represented by formula (2) in which R^{3a} and R^{3b} are each independently a methyl group or an ethyl group, R^{3c} is a phenyl group, and R⁴ is a phenyl group or a benzyl group is more preferable.

In formula (3), examples of the hydrocarbon group represented by R^{5a}, R^{5b}, R^{5c} and R⁶ include linear, branched, or cyclic, saturated or unsaturated hydrocarbon groups having from 1 to 20 carbon atoms, and among them, a linear, branched, or cyclic, saturated or unsaturated hydrocarbon group having from 1 to 12 carbon atoms is preferable. Examples of the hydrocarbon group include linear, branched, or cyclic saturated aliphatic hydrocarbon groups having from 1 to 20 carbon atoms, such as a methyl group, an ethyl group, an n-propyl group, an isopropyl group, an n-butyl group, an isobutyl group, a tert-butyl group, a cyclohexyl group, a dodecyl group and an octadecyl group; aryl groups having from 6 to 12 carbon atoms, such as a phenyl group; and arylalkyl groups having from 7 to 10 carbon atoms, such as a benzyl group and a phenethyl group. In formula (3), examples of the hydrocarbon group which may be substituted with an alkoxy group and represented by R^{5c} include groups in which from 1 to 3 hydrogen atoms in the above-described hydrocarbon group are substituted with alkoxy groups.

In formula (4), examples of the hydrocarbon group represented by R^{7a}, R^{7b}, R⁸, and R⁹ include linear, branched, or cyclic, saturated or unsaturated hydrocarbon groups having from 1 to 20 carbon atoms, and among them, a linear, branched, or cyclic, saturated or unsaturated hydrocarbon group having from 1 to 12 carbon atoms is preferable. Examples of the hydrocarbon group include linear, branched, or cyclic saturated aliphatic hydrocarbon groups having from 1 to 20 carbon atoms, such as a methyl group, an ethyl group, an n-propyl group, an isopropyl group, an n-butyl group, an isobutyl group, a tert-butyl group, a cyclohexyl group, a dodecyl group and an octadecyl group; aryl groups having from 6 to 12 carbon atoms, such as a phenyl group; and arylalkyl groups having from 7 to 10 carbon atoms, such as a benzyl group and a phenethyl group. R⁸ and R⁹ may form a pyrazole ring together with the nitrogen atom of formula (4). The pyrazole ring may be substituted with a saturated aliphatic hydrocarbon group having from 1 to 3 carbon atoms or a chlorine atom.

Many of the RAFT agents are commercially available. Those which are not commercially available can be easily synthesized by known or commonly used methods.

Specific examples of the RAFT agent include trithiocarbonates, such as S-cyanomethyl-S-dodecyl trithiocarbonate, 2-[(dodecylsulfanylthiocarbonyl) sulfanyl]propanoic acid, 2-{[(2-carboxyethyl) sulfanylthiocarbonyl]sulfanyl}propanoic acid, 4-[(2-carboxyethylsulfanylthiocarbonyl) sulfanyl]-4-cyanopentanoic acid, 4-cyano-4-[(dodecylsulfanylthiocarbonyl) sulfanyl]pentanoic acid, methyl 4-cyano-4-[(dodecylsulfanylthiocarbonyl) sulfanyl]pentanoate, 2-cyano-2-propyldodecyl trithiocarbonate, and benzyldodecyl trithiocarbonate; dithioesters, such as cyanoethyl dithiopropionate, benzyl dithiopropionate, benzyl dithiobenzoate, acetoxyethyl dithiobenzoate, 2-phenyl-2-propyldithiobenzoic acid, 2-cyano-2-propyldithiobenzoic acid, 4-cyano-4-(phenylcarbonothioylthio) pentanoic acid, S-(thiobenzoyl)thioglycolic acid; dithiocarbonates, such as ethyl 2-[(ethoxycarbonothioyl)thio]propionate, O-ethyl-S-(2-propoxyethyl)dithiocarbonate, and O-ethyl-S-(1-cyano-1-methylethyl)dithiocarbonate; and dithiocarbamates, such as 2-cyano-2-propyldiethyldithiocarbamate, 2′-cyanobutan-2′-yl 4-chloro-3,5-dimethylpyrazole-1-dithiocarbamate, 2′-cyanobutan-2′-yl 3,5-dimethylpyrazole-1-dithiocarbamate, cyanomethyl 3,5-dimethylpyrazole-1-dithiocarbamate, and cyanomethyl N-methyl-N-phenyldithiocarbamate. Among these, from the viewpoint of ease of polymerization of the (meth)acrylic resin (A), trithiocarbonates and dithioesters are preferable, and 2-[(dodecylsulfanylthiocarbonyl) sulfanyl]propanoic acid, 4-cyano-4-[(dodecylsulfanylthiocarbonyl) sulfanyl]pentanoic acid, 2-{[(2-carboxyethyl) sulfanylthiocarbonyl]sulfanyl}propanoic acid, benzyldodecyl trithiocarbonate, and 2-phenyl-2-propyldithiobenzoic acid are more preferable.

The RAFT agent may be used alone or in combination of two or more thereof.

When step (i-2) is performed before step (i-1), a diblock type copolymer in which a block synthesized from the raw material monomer group (m-X) is connected to a block synthesized from the raw material monomer group (m-Y) is obtained by continuously using the RAFT agent blended in step (i-2).

An amount of the RAFT agent used is preferably from 0.001 to 1.0 parts by mass, more preferably from 0.005 to 0.5 parts by mass, and still more preferably from 0.01 to 0.35 parts by mass, per 100 parts by mass of the total of the raw material monomer group (m-X), the raw material monomer group (m-Y), and the optionally used ethylenically unsaturated compound having a functional group, such as an isocyanato group. When the amount is 0.001 parts by mass or more, polymerization can be carried out in an efficient reaction time. When the amount is 1.0 parts by mass or less, a block having a sufficiently high molecular weight is obtained.

### (Radical Polymerization Initiator)

The RAFT polymerization is preferably carried out in the presence of a radical polymerization initiator. Examples of the radical polymerization initiator include common organic radical polymerization initiators, and specific examples thereof include oil-soluble polymerization initiators, such as azo-based polymerization initiators including 2,2′-azobis(isobutyronitrile), 2,2′-azobis(4-methoxy-2,4-dimethylvaleronitrile), 2,2′-azobis(2,4-dimethylvaleronitrile), 2,2′-azobis (2-methylbutyronitrile), 1,1′-azobis (cyclohexane-1-carbonitrile), 2,2′-azobis(2,4,4-trimethylpentane), dimethyl-2,2′-azobis (2-methylpropionate), and 2,2′-azobis (N-butyl-2-methylpropionamide; and peroxide-based polymerization initiators including benzoyl peroxide, t-butyl hydroperoxide, di-t-butyl peroxide, t-butyl peroxybenzoate, dicumyl peroxide, 1,1-bis (t-butylperoxy)-3,3,5-trimethylcyclohexane, and 1,1-bis(t-butylperoxy)cyclododecane.

Among these radical polymerization initiators, from the viewpoint of 10-hour half-life temperature and solubility in organic solvents, an azo-based polymerization initiator is preferable, and it is more preferable to use at least one selected from 2,2′-azobis (isobutyronitrile), 2,2′-azobis(4-methoxy-2,4-dimethylvaleronitrile), 2,2′-azobis(2,4-dimethylvaleronitrile), 2,2′-azobis (2-methylbutyronitrile), and 2,2′-azobis (N-butyl-2-methylpropionamide).

The radical polymerization initiator may be used alone or in combination of two or more thereof.

When step (i-2) is performed before step (i-1), the radical polymerization initiator blended in step (i-2) may be continuously used, or a radical polymerization initiator may be further added in step (i-1) in order to compensate for the radical polymerization initiator deactivated in step (i-2). The radical polymerization initiator is preferably further added in step (i-1) from the viewpoint of reactivity and molecular weight control.

An amount of the radical polymerization initiator to be added in step (i-1) is preferably from 0.0001 to 1.0 parts by mass, more preferably from 0.001 to 0.5 parts by mass, and still more preferably from 0.005 to 0.1 parts by mass, per 100 parts by mass of the total amount of the raw material monomer group (m-X), the raw material monomer group (m-Y), and the optionally used ethylenically unsaturated compound having a functional group, such as an isocyanato group. When the amount is 0.0001 parts by mass or more, polymerization can be performed in an efficient reaction time. When the amount is 1.0 parts by mass or less, a block having a sufficiently high molecular weight is obtained.

The molar ratio of the radical generated from the radical polymerization initiator added in step (i-1) to the RAFT agent is preferably from 1.0:1.0 to 1.0:1.5 from the viewpoint of allowing living radical polymerization to proceed preferentially over free radical polymerization.

### (Solvent)

As the solvent which may be used in step (i-1), a general solvent can be used. Examples of the solvent include esters, such as ethyl acetate, propyl acetate, and butyl acetate; aromatic hydrocarbons, such as toluene, xylene, and benzene; aliphatic hydrocarbons, such as hexane and heptane; alicyclic hydrocarbons, such as cyclohexane and methylcyclohexane; ketones, such as methyl ethyl ketone and methyl isobutyl ketone; glycols, such as ethylene glycol, propylene glycol, and dipropylene glycol; glycol ethers, such as methyl cellosolve, propylene glycol monomethyl ether, and dipropylene glycol monomethyl ether; and glycol esters, such as ethylene glycol diacetate and propylene glycol monomethyl ether acetate. The solvent may be used alone or in combination of two or more thereof.

When step (i-2) is performed before step (i-1), the solvent blended in step (i-2) may be continuously used, or a solvent may be further added in step (i-1).

### Step (i-2)

In step (i-2), in the presence of a reversible addition-fragmentation chain transfer agent (RAFT agent), a raw material monomer group (m-Y) containing an ethylenically unsaturated compound (m-3) having an SP value of 20 (J/cm³)^{1/2} or less and optionally a monomer other than (m-3) are subjected to RAFT polymerization.

Conditions, such as reaction temperature, reaction time, polymerization method, and concentration can be appropriately set in the same manner as in step (i-1).

The RAFT agent used may be the same as that used in step (i-1), and preferred RAFT agents are also the same. When step (i-1) is performed before step (i-2), a diblock type copolymer in which a block synthesized from the raw material monomer group (m-Y) is connected to a block synthesized from the raw material monomer group (m-X) is obtained by continuously using the RAFT agent blended in step (i-1).

The radical polymerization initiator used may be the same as that used in step (i-1), and preferred radical polymerization initiators are also the same. When step (i-1) is performed before step (i-2), the radical polymerization initiator blended in step (i-1) may be continuously used, or a radical polymerization initiator may be further added in step (i-2) in order to compensate for the radical polymerization initiator deactivated in step (i-1). The radical polymerization initiator is preferably further added in step (i-2) from the viewpoint of reactivity and molecular weight control.

An amount of the radical polymerization initiator to be added in step (i-2) is preferably from 0.0001 to 1.0 parts by mass, more preferably from 0.001 to 0.5 parts by mass, and still more preferably from 0.005 to 0.1 parts by mass, per 100 parts by mass of the total amount of the raw material monomer group (m-X), the raw material monomer group (m-Y), and the optionally used ethylenically unsaturated compound having a functional group, such as an isocyanato group. When the amount is 0.0001 parts by mass or more, polymerization can be performed in an efficient reaction time. When the amount is 1.0 parts by mass or less, a block having a sufficiently high molecular weight is obtained.

The molar ratio of the radical generated from the radical polymerization initiator added in step (i-2) to the RAFT agent is preferably from 1.0:1.0 to 1.0:1.5 from the viewpoint of allowing living radical polymerization to proceed preferentially over free radical polymerization. The solvent used may be the same as that used in step (i-1). When step (i-1) is performed before step (i-2), the solvent blended in step (i-1) may be continuously used, or a solvent may be further added in step (i-2).

### Step (ii)

Step (ii) is a step of introducing an ethylenically unsaturated group by adding an ethylenically unsaturated compound to a part of side chain hydroxy groups in the copolymer obtained by step (i-1) and step (i-2). When the ethylenically unsaturated compound is added to all of the side chain hydroxy groups of the copolymer obtained by steps (i-1) and (i-2), the resulting copolymer does not contain hydroxy groups, and the pressure-sensitive adhesive strength of a pressure-sensitive adhesive sheet becomes insufficient. In addition, when the ethylenically unsaturated compound is added to all of the side chain hydroxy groups of the copolymer obtained by step (i-1) and step (i-2), there is no reaction site with the crosslinking agent (C) described later. Thus, the addition is limited to a part of the side chain hydroxy groups. Specifically, when the amount of the side chain hydroxy groups is 100 mol %, the amount of the side chain hydroxy groups to be subjected to the addition reaction is preferably from 40 to 99 mol %. The method for adding the ethylenically unsaturated compound is not particularly limited, and a method known in the technical field of the present specification can be used. Since the (meth)acrylic resin (A) has an ethylenically unsaturated group in the side chain, the length of a molecular chain between crosslinking points is relatively short as compared with a (meth)acrylic copolymer in which an ethylenically unsaturated group is introduced into a terminal, and the crosslinking density can be efficiently improved by UV irradiation. Therefore, when the (meth)acrylic resin (A) is used as a material for a pressure-sensitive adhesive, the pressure-sensitive adhesive strength after UV irradiation can be greatly reduced. Therefore, the pressure-sensitive adhesive sheet containing the (meth)acrylic resin (A) is excellent in releasability from an adherend. In addition, the pressure-sensitive adhesive composition produced using the (meth)acrylic resin (A) has excellent adhesiveness to an adhesive layer. Therefore, the pressure-sensitive adhesive composition produced using the (meth)acrylic resin (A) is suitably used in the pressure-sensitive adhesive layer of a dicing tape.

### (Catalyst)

In the addition reaction in step (ii), a known catalyst can be used as necessary. As a catalyst for adding the isocyanato group-containing ethylenically unsaturated compound (a) to the side chain hydroxy groups, for example, a urethane formation catalyst, such as dibutyltin dilaurate, titanium diisopropoxybis (ethylacetoacetate), tetrakis (2,4-pentanedionato) zirconium, or bismuth tris (2-ethylhexanoate) can be used.

When the catalyst is used in the addition of the isocyanato group-containing ethylenically unsaturated compound (a) to the side chain hydroxy groups in step (ii), an amount of the catalyst used is preferably from 0.01 to 10 parts by mass, more preferably from 0.02 to 5 parts by mass, and still more preferably from 0.03 to 1 parts by mass, per 100 parts by mass of a total of the copolymer obtained by steps (i-1) and (i-2) and the isocyanato group-containing ethylenically unsaturated compound (a).

### (Polymerization Inhibitor)

In the addition reaction in step (ii), a known polymerization inhibitor can be used as necessary. As the polymerization inhibitor, a known polymerization inhibitor can be used, and is not particularly limited, and examples thereof include 4-methoxyphenol, hydroquinone, methoquinone, 2,6-di-t-butylphenol, 2,2′-methylenebis(4-methyl-6-t-butylphenol), and phenothiazine. The polymerization inhibitor may be used alone or in combination of two or more thereof.

When the polymerization inhibitor is used in step (ii), an amount of the polymerization inhibitor used is preferably from 0.005 to 5 parts by mass, more preferably from 0.03 to 3 parts by mass, and still more preferably from 0.05 to 1.5 parts by mass, per 100 parts by mass of the total of the copolymer obtained in steps (i-1) and (i-2) and the ethylenically unsaturated compound. When the amount of the polymerization inhibitor used is 0.005 parts by mass or more, gelation during the addition reaction can be prevented. In contrast, when the amount of the polymerization inhibitor used is 5 parts by mass or less, there can be obtained an adequate exposure sensitivity of the (meth)acrylic resin (A) upon UV irradiation.

### (Reaction Conditions)

A temperature of the addition reaction is preferably from 25° C. to 130° C., and particularly preferably from 40° C. to 90° C. When the temperature for the addition reaction is 25° C. or higher, an adequate reaction speed can be obtained. When the temperature of the addition reaction is 130° C. or lower, there can be prevented the occurrence of a gelled product due to crosslinked double bond portion through radical polymerization by heat.

Furthermore, at the time of the addition reaction, a gas effective to inhibit polymerization may be introduced into the reaction system. When the gas effective to inhibit polymerization is introduced into the reaction system, gelation during the addition reaction can be prevented.

Examples of the gas effective to inhibit polymerization include a gas that contains oxygen to the extent that does not fall within the explosion range of the substance in the system, for example, air.

Combined use of a gas effective to inhibit a polymerization and a polymerization inhibitor is more preferable because the amount of the polymerization inhibitor to be used can be reduced or the effect to inhibit polymerization can be enhanced.

### Method for Producing Pressure-Sensitive Adhesive Composition

### Step (iii)

The pressure-sensitive adhesive composition can be produced, for example, by a method including step (iii) of mixing the (meth)acrylic resin (A), the photopolymerization initiator (B), the crosslinking agent (C), and an additional component to be added as necessary. The method for mixing the components to be contained in the pressure-sensitive adhesive composition is not particularly limited. The mixing can be performed by using, for example, a homogenizing disper or an agitator equipped with a stirring blade, such as a paddle blade.

### Method for Producing Photocrosslinkable Pressure-Sensitive Adhesive

### Step (iv)

The photocrosslinkable pressure-sensitive adhesive can be produced, for example, by a method including step (iv) of applying a pressure-sensitive adhesive composition onto a base material or a release sheet and thermally curing the pressure-sensitive adhesive composition.

The pressure-sensitive adhesive composition obtained in step (iii) may be used as it is, or a pressure-sensitive adhesive composition whose viscosity is adjusted by further adding a solvent may be used.

Thermosetting proceeds by heat-drying and curing as necessary in the process of forming the photocrosslinkable pressure-sensitive adhesive. For example, as an embodiment of step (iv), a pressure-sensitive adhesive composition is applied onto a base material. When the pressure-sensitive adhesive composition contains a solvent, the solvent is removed by heat-drying, to form a pressure-sensitive adhesive composition layer. Thereafter, a release sheet is bonded onto the pressure-sensitive adhesive composition layer as necessary. Further, if necessary, the obtained sheet is cured in an oven for a certain period of time to form a crosslinked structure, whereby a layer of the photocrosslinkable pressure-sensitive adhesive can be obtained.

According to another embodiment, step (iv) includes step (iv-1) of applying a pressure-sensitive adhesive composition onto a release sheet to obtain a pressure-sensitive adhesive composition layer, step (iv-2) of thermally curing the pressure-sensitive adhesive composition layer to obtain a photocrosslinkable pressure-sensitive adhesive layer, and step (iv-3) of laminating a base material on the pressure-sensitive adhesive composition layer or the photocrosslinkable pressure-sensitive adhesive layer. Step (iv-3) may be performed between step (iv-1) and step (iv-2), or may be performed after step (iv-2). For example, a pressure-sensitive adhesive composition is applied onto a release sheet. When the pressure-sensitive adhesive composition contains a solvent, the solvent is removed by heat-drying, to form a pressure-sensitive adhesive composition layer (step (iv-1)). Thereafter, the release sheet including the pressure-sensitive adhesive composition layer is placed on the base material with the surface on the side of the pressure-sensitive adhesive composition layer facing the base material, and the pressure-sensitive adhesive composition layer is transferred onto the base material (step (iv-3)). Further, if necessary, the obtained sheet is cured in an oven for a certain period of time to form a crosslinked structure, whereby a photocrosslinkable pressure-sensitive adhesive layer can be obtained (step (iv-2)).

As a method for applying the pressure-sensitive adhesive composition onto the base material or the release sheet, a known method can be used. Specific examples of the method include a method in which coating is performed with a common use coater, such as a gravure roll coater, a reverse roll coater, a kiss roll coater, a dip roll coater, a bar coater, a knife coater, a spray coater, a comma coater, or a direct coater.

The conditions for heat-drying the applied pressure-sensitive adhesive composition are not particularly limited, but the heat-drying are carried out usually at a temperature of from 25 to 180° C., and preferably from 60 to 150° C., and usually for a period of time from 1 to 20 minutes, and preferably from 1 to 10 minutes. When the heat-drying are carried out within the abovementioned range, the solvent contained in the pressure-sensitive adhesive composition can be removed. The conditions for curing the heat-dried sheet in an oven for a certain period of time are not particularly limited, but curing is carried out usually at a temperature of from 25 to 100° C., preferably from 30 to 80° C., and usually for a period of time from 1 to 30 days, preferably from 1 to 14 days. When the curing is carried out under the above conditions, the (meth)acrylic resin (A) can be crosslinked with the crosslinking agent (C), whereby a gel fraction of the photocrosslinkable pressure-sensitive adhesive can be adjusted to be within a desired range.

### [Pressure-sensitive Adhesive Sheet]

The pressure-sensitive adhesive sheet includes a base material layer and a pressure-sensitive adhesive layer composed of a thermally cured product or photothermally cured product of a pressure-sensitive adhesive composition. If necessary, the pressure-sensitive adhesive sheet may include a release sheet on an exposed surface of the pressure-sensitive adhesive layer (i.e., a surface opposite to the base material layer) before the pressure-sensitive adhesive sheet is attached to an adherend. The pressure-sensitive adhesive sheet can be obtained, for example, by step (iv). The pressure-sensitive adhesive layer is used in the state of a photocrosslinkable pressure-sensitive adhesive layer when it is attached to an adherend, and when it is peeled off from the adherend, it is peeled off in a state where the photocrosslinkable pressure-sensitive adhesive layer is crosslinked by UV irradiation to reduce the pressure-sensitive adhesive strength.

The base material is not particularly limited and may be appropriately selected depending on the application. In general, a resin film is preferable, and examples of a resin material include polyvinyl chloride, polyvinylidene chloride, polyolefin (PO), polyester, polyurethane, polycarbonate, polyetheretherketone, polyimide, polyetherimide, polyamide, wholly aromatic polyamide (aramid), polyphenylene sulfide, a fluororesin, a cellulose-based resin, and a silicone resin. Examples of the polyolefin include polyethylene (PE), such as low-density polyethylene, linear polyethylene, medium-density polyethylene, high-density polyethylene, and ultralow-density polyethylene; polypropylene (PP), such as random copolymer polypropylene, block copolymer polypropylene, and homopolypropylene; polybutene; polymethylpentene; ethylene-vinyl acetate copolymer; ionomer resin; ethylene-(meth)acrylic acid copolymer; ethylene-(meth)acrylic ester copolymer; ethylene-butene copolymer; and ethylene-hexene copolymer. Examples of the polyester include polyethylene terephthalate (PET), polyethylene naphthalate, and polybutylene terephthalate (PBT). Among these resin materials, it is particularly preferable to use one or more selected from the group consisting of PE, PP, and PET because a pressure-sensitive adhesive sheet having appropriate flexibility can be obtained. The resin material used as the material for the base material may be used alone or in combination of two or more thereof. When it is used for a dicing tape, polyolefin is preferably used.

The base material may be made of one type of material or may be made of two or more types of materials. The base material may have a single-layer structure or a multilayer structure. Since the photocrosslinkable pressure-sensitive adhesive on the base material is ultraviolet-curable, the base material preferably has ultraviolet transparency. When the base material is a resin film, the base material may be a non-stretched film, a uniaxially stretched film, or a biaxially stretched film.

The base material may be subjected to a treatment for enhancing adhesiveness. Examples of such a treatment include physical treatments, such as corona discharge treatment, plasma treatment, sand matting treatment, ozone exposure treatment, flame exposure treatment, high-voltage electric shock exposure treatment, and ionizing radiation treatment; chemical treatments, such as chromic acid treatment; and undercoating treatment.

As the base material, a PO film is preferably used. The PO film has low heat resistance and is not suitable for the heat-drying temperature described above. Therefore, preferably, the pressure-sensitive adhesive composition is applied to the release sheet, heat-dried to remove the solvent, and then the pressure-sensitive adhesive composition layer is transferred to the PO film. Specifically, preferably, the pressure-sensitive adhesive composition is applied to a release-treated surface of a silicone-based easy-release PET film and heat-dried, and the PO film is attached to the pressure-sensitive adhesive composition layer using a rubber roller so that the corona-treated surface of the PO film adheres to the exposed surface of the pressure-sensitive adhesive composition layer.

The release sheet is not particularly limited, and for example, those generally used for pressure-sensitive adhesive applications can be used without limitation. Specifically, the same resin film as that used for the base material is preferable, and from the viewpoint of handleability, it is preferable to use a resin film containing one or more types selected from PE, PP, and PET.

The release sheet may be subjected to a release treatment in order to impart easy releasability. Specific examples of the treatment include a release treatment with silicone.

A thickness of the photocrosslinkable pressure-sensitive adhesive layer is preferably from 5 to 100 μm, more preferably from 10 to 50 μm, and still more preferably from 10 to 20 μm. When the thickness of the photocrosslinkable pressure-sensitive adhesive layer is 5 μm or more, sufficient pressure-sensitive adhesive properties are exhibited, and coating is easy. When the thickness of the photocrosslinkable pressure-sensitive adhesive layer is 100 μm or less, generation of bubbles during heat-drying and remaining of the solvent can be suppressed.

### [Use of Pressure-sensitive Adhesive Sheet]

The pressure-sensitive adhesive sheet can be used as a removable pressure-sensitive adhesive sheet, for example, when an electronic component is produced. Specifically, the removable pressure-sensitive adhesive sheet can be used as a surface protective tape for protecting the surface of an adherend in each step of producing an electronic component. The pressure-sensitive adhesive sheet can also be used for a purpose of fixing an adherend in each step of producing an electronic component, subjecting the adherend to various processing steps, and then peeling off the adherend by irradiation with UV (ultraviolet rays). Therefore, the pressure-sensitive adhesive sheet can be used as a back grinding tape, a dicing tape, a dicing/die bonding integrated film, or the like in processing a semiconductor wafer. The pressure-sensitive adhesive sheet can also be used as a supporting tape for a fragile member, such as an ultrathin glass substrate and a member that is easily warped, such as an FPC substrate. In particular, since the pressure-sensitive adhesive sheet has excellent water resistance and sufficient pressure-sensitive adhesive strength to an adherend, it is suitable for a dicing tape and a dicing/die bonding integrated film.

### [Dicing Tape]

The dicing tape includes a base material layer and a pressure-sensitive adhesive layer composed of a thermally cured product or photothermally cured product of a pressure-sensitive adhesive composition.

An exemplary method of using the pressure-sensitive adhesive sheet as a dicing tape for a wafer will be described below. Before performing a dicing step, a pressure-sensitive adhesive sheet is attached to a wafer on which a plurality of components are formed. Next, the wafer is cut (diced) into individual components to obtain small element pieces (chips). Thereafter, the pressure-sensitive adhesive sheet attached on each element piece is irradiated with UV. As a result, the photocrosslinkable pressure-sensitive adhesive layer is irradiated with UV through the base material of the pressure-sensitive adhesive sheet, the unsaturated bond in the photocrosslinkable pressure-sensitive adhesive forms a three dimensional crosslinked structure, and the layer is set. As a result, the pressure-sensitive adhesive strength of the pressure-sensitive adhesive layer is reduced. Thereafter, the pressure-sensitive adhesive sheet is peeled off from each element piece.

### [Method for Producing Dicing Tape]

The dicing tape can be produced, for example, by forming a photocrosslinkable pressure-sensitive adhesive layer on a base material. The photocrosslinkable pressure-sensitive adhesive layer can be formed, for example, by the same method as in step (iv).

The base material is preferably made of a material suitable for an expanding step, and is preferably a polyolefin film.

When a polyolefin film is used, heating at the time of forming the photocrosslinkable pressure-sensitive adhesive layer may cause a problem from the viewpoint of heat resistance. Therefore, it is preferable to carry out the following steps in this order:
(iv-1) applying a pressure-sensitive adhesive composition onto a release sheet to obtain a pressure-sensitive adhesive composition layer;
(iv-2) thermally curing the pressure-sensitive adhesive composition layer to obtain a photocrosslinkable pressure-sensitive adhesive layer; and
(iv-3) laminating a base material on the photocrosslinkable pressure-sensitive adhesive layer, and
to cure the obtained sheet in an oven for a certain period of time, as necessary, to form a crosslinked structure, thereby obtaining a dicing tape.

A thickness of the photocrosslinkable pressure-sensitive adhesive layer is preferably from 5 to 100 μm, more preferably from 10 to 50 μm, and still more preferably from 10 to 20 μm. When the thickness of the photocrosslinkable pressure-sensitive adhesive layer is 5 μm or more, sufficient pressure-sensitive adhesive properties are exhibited, and coating is easy. When the thickness of the photocrosslinkable pressure-sensitive adhesive layer is 100 μm or less, generation of bubbles during heat-drying and remaining of the solvent can be suppressed. In particular, when the thickness of the photocrosslinkable pressure-sensitive adhesive layer is from 10 to 20 μm, sufficient releasability and separability (cutting property) can be obtained.

### [Dicing/Die Bonding Integrated Film]

The dicing/die bonding integrated film includes a base material layer, a pressure-sensitive adhesive layer composed of a thermally cured product or photothermally cured product of a pressure-sensitive adhesive composition, and an adhesive layer in this order.

### [Method for Producing Dicing/Die Bonding Integrated Film]

The dicing/die bonding integrated film can be obtained, for example, by laminating a dicing tape and a die bonding tape. The dicing tape can be produced by, for example, the same method as in the above-described producing method.

Examples of the method for producing the dicing/die bonding integrated film include a method including the following steps:
(iv-1) applying a pressure-sensitive adhesive composition onto a release sheet to obtain a pressure-sensitive adhesive composition layer;
(iv-2) thermally curing the pressure-sensitive adhesive composition layer to obtain a photocrosslinkable pressure-sensitive adhesive layer; and
(iv-3) laminating a base material on the pressure-sensitive adhesive composition layer or the photocrosslinkable pressure-sensitive adhesive layer to obtain a dicing tape; and
(v) laminating the dicing tape and a die bonding tape.

The order of the steps may be changed, except that step (iv-1) is performed first and step (v) is performed last. Step (iv-3) may be performed between step (iv-1) and step (iv-2), or may be performed after step (iv-2).

A thickness of the photocrosslinkable pressure-sensitive adhesive layer is preferably from 5 to 100 μm, more preferably from 10 to 50 μm, and still more preferably from 10 to 20 μm. When the thickness of the photocrosslinkable pressure-sensitive adhesive layer is 5 μm or more, sufficient pressure-sensitive adhesive properties are exhibited, and coating is easy. When the thickness of the photocrosslinkable pressure-sensitive adhesive layer is 100 μm or less, generation of bubbles during heat-drying and remaining of the solvent can be suppressed. In particular, when the thickness of the photocrosslinkable pressure-sensitive adhesive layer is from 10 to 20 μm, sufficient releasability and separability (cutting property) can be obtained.

Step (v) can be performed by, for example, preparing a die bonding tape and pressure-bonding the die bonding tape to the dicing tape. The die bonding tape can be obtained, for example, by applying an adhesive composition onto a release sheet and setting the adhesive composition to form an adhesive layer. A bonding temperature is, for example, from 30 to 50° C. A bonding pressure (linear pressure) is, for example, from 0.1 to 20 kgf/cm.

As a modified example of the method for producing a dicing/die bonding integrated film, the thermal curing of the pressure-sensitive adhesive composition may be performed in two steps of step (iv-2) and step (v). For example, after the thermal curing is allowed to proceed in step (iv-2), the dicing tape and the die bonding tape may be laminated in step (v) and then cured to further allow the thermal curing of the photocrosslinkable pressure-sensitive adhesive layer to proceed.

As a modified example of the method for producing a dicing/die bonding integrated film, the release sheet in step (iv-1) may be replaced with the die bonding tape in step (v), and the formation of the photocrosslinkable pressure-sensitive adhesive layer and the lamination of the dicing tape and the die bonding tape may be performed at once. In this case, the dicing/die bonding integrated film can be obtained by applying the pressure-sensitive adhesive composition onto the adhesive layer of the die bonding tape, thermally curing the composition, and laminating the base material before or after the thermal curing.

### Method for Producing Cured Product (Photothermally Cured Product) of Photocrosslinkable Pressure-Sensitive Adhesive

### Step (vi)

The cured product of the photocrosslinkable pressure-sensitive adhesive (also referred to as photothermally cured product) can be produced, for example, by a method including step (vi) of irradiating the photocrosslinkable pressure-sensitive adhesive with UV to form a crosslinked structure.

Examples of the light source used when UV irradiation is performed include a high-pressure mercury lamp, an ultra-high pressure mercury lamp, a carbon arc lamp, a xenon lamp, a metal halide lamp, a chemical lamp, and a black light.

An irradiation amount of UV with which the photocrosslinkable pressure-sensitive adhesive is irradiated is preferably from 50 to 3000 mJ/cm², and more preferably from 100 to 600 mJ/cm². When the irradiation amount of UV with which the photocrosslinkable pressure-sensitive adhesive is irradiated is 50 mJ/cm² or more, the crosslinking density of the photocrosslinkable pressure-sensitive adhesive can be improved at a sufficiently high setting rate by UV irradiation. Therefore, when the photocrosslinkable pressure-sensitive adhesive is used in the pressure-sensitive adhesive layer, the pressure-sensitive adhesive strength of the pressure-sensitive adhesive layer after UV irradiation can be sufficiently reduced. When the photocrosslinkable pressure-sensitive adhesive is used in the resist, the strength can be improved. Even if the irradiation amount of UV with which the photocrosslinkable pressure-sensitive adhesive is irradiated exceeds 3000 mJ/cm², the effect of further improving the crosslinking density cannot be obtained. Therefore, by adjusting the UV irradiation amount to 3000 mJ/cm² or less, a cured product can be economically produced while reducing the influence of UV irradiation on an adherend. Therefore, when the photocrosslinkable pressure-sensitive adhesive is used in the pressure-sensitive adhesive sheet, the sheet can be economically peeled off.

### EXAMPLES

Hereinafter, the present invention will be described more specifically with reference to Examples and Comparative Examples, but the present invention is not limited to the following Examples.

The raw materials used in the synthesis of the (meth)acrylic resins (A) and (cA) are shown below. In Table 1, the SP value (J/cm³)^{1/2} is also shown with the compound name of the raw material monomer.

### Raw Material Monomer:

2-Hydroxyethyl acrylate, Osaka Organic Chemical Industry Ltd.
Styrene, Asahi Kasei Corporation
Isostearyl acrylate, Osaka Organic Chemical Industry Ltd.
n-Butyl acrylate, Osaka Organic Chemical Industry Ltd.
Cyclohexyl acrylate, Osaka Organic Chemical Industry Ltd.
Methyl acrylate, NIPPON SHOKUBAI CO., LTD.
Methyl methacrylate, NIPPON SHOKUBAI CO., LTD.
Isopropenyl methacrylate, Kuraray Co., Ltd.

### Radical Polymerization Initiator:

2,2′-Azobis (N-butyl-2-methylpropionamide), FUJIFILM Wako Pure Chemical Corporation
2,2′-Azobis (isobutyronitrile), FUJIFILM Wako Pure Chemical Corporation
2,2′-Azobis (2,4-dimethylvaleronitrile), FUJIFILM Wako Pure Chemical Corporation RAFT agent:
Benzyldodecyl trithiocarbonate, FUJIFILM Wako Pure Chemical Corporation
4-Cyano-4-[(dodecylsulfanylthiocarbonyl) sulfanyl]pentanoic acid, FUJIFILM Wako Pure Chemical Corporation
Trithiocarbonic acid bis[[4-[[ethyl-(2-acetoxyethyl)amino]carbonyl]phenyl]methyl]ester, FUJIFILM Wako Pure Chemical Corporation
2-Cyano-2-propyldodecyl trithiocarbonate, FUJIFILM Wako Pure Chemical Corporation
Isocyanato group-containing ethylenically unsaturated compound (a):
Karenz (trademark) MOI, 2-isocyanatoethyl methacrylate, Resonac Corporation
AOI-VM (trademark), 2-isocyanatoethyl acrylate, Resonac Corporation

Synthesis examples of the (meth)acrylic resins (A) and (cA) are shown below. The weight average molecular weights (Mw), the molecular weight distributions (Mw/Mn), and the hydroxyl values of the (meth)acrylic resins (A) and (cA) were measured and calculated by the above-described methods. The ethylenically unsaturated group equivalents of the (meth)acrylic resins (A) and (cA) were calculated from the charged amounts as described above.

### Synthesis Example 1

### Step i-2

A reaction device equipped with a stirrer, a temperature controller, a reflux condenser, a dropping funnel, and a thermometer was charged with 25 mol of styrene, 0.118 parts by mass of benzyldodecyl trithiocarbonate per 100 parts by mass of the total of the raw material monomer groups (m-X) and (m-Y) and the isocyanato group-containing ethylenically unsaturated compound (a), 0.0417 parts by mass of 2,2′-azobis (N-butyl-2-methylpropionamide) per 100 parts by mass of the total of the raw material monomer groups (m-X) and (m-Y) and the isocyanato group-containing ethylenically unsaturated compound (a), and butyl acetate as a solvent so that the total concentration of the raw material monomer group (m-Y), the RAFT agent, and the radical polymerization initiator was 80 mass %. After the temperature was raised to 120° C., the reaction was carried out for 14 hours.

### Step i-1

Subsequently, 58 mol of n-butyl acrylate, 17 mol of 2-hydroxyethyl acrylate, 0.0417 parts by mass of 2,2′-azobis (N-butyl-2-methylpropionamide) per 100 parts by mass of the total of the raw material monomer groups (m-X) and (m-Y) and the isocyanato group-containing ethylenically unsaturated compound (a), and butyl acetate as a solvent were charged so that the total concentration of the polymer obtained in step (i-2), the raw material monomer group (m-X), and the radical polymerization initiator added in step (i-1) was 80 mass %. After the temperature was raised to 120° C., the reaction was carried out for 14 hours.

### Step ii

Next, the reaction product was cooled to room temperature and diluted with butyl acetate so that the concentration of the copolymer obtained in step (i-1) was 40 mass %. Next, the temperature of the diluted reaction product was raised to 55° C., and a mixed liquid of 16 mol of 2-isocyanatoethyl acrylate and dibutyltin dilaurate as a urethane formation catalyst was added dropwise through the dropping funnel. The amount of dibutyltin dilaurate blended was 0.06 parts by mass per 100 parts by mass of the total of the copolymer obtained in step (i-1) and the isocyanato group-containing ethylenically unsaturated compound (a). After completion of the dropwise addition, the reaction system was retained at 60° C. for 4 hours to eliminate the isocyanate group. Thus, a liquid containing a (meth)acrylic resin (A1) having a weight average molecular weight of 300,000, a molecular weight distribution of 2.6, an ethylenically unsaturated group equivalent of 905 g/mol, and a hydroxyl value of 5.05 mgKOH/g and having a solids content of 40 mass % was obtained.

### Synthesis Examples 2 to 7

(Meth)acrylic resins (A2) to (A7) were obtained in the same manner as in Synthesis Example 1 except that the compositions shown in Table 1 were used. In Synthesis Example 3, step (ii) was not carried out.

### Comparative Synthesis Example 1

### Step i-1

A reaction device equipped with a stirrer, a temperature controller, a reflux condenser, a dropping funnel and a thermometer was charged with 6 mol of n-butyl acrylate, 16 mol of 2-hydroxyethyl acrylate, 0.260 parts by mass of trithiocarbonic acid bis[[4-[[ethyl-(2-acetoxyethyl)amino]carbonyl]phenyl]methyl]ester per 100 parts by mass of the total of the raw material monomer groups (m-X) and (m-Y) and the isocyanato group-containing ethylenically unsaturated compound (a), 0.0160 parts by mass of 2,2′-azobis(2,4-dimethylvaleronitrile) per 100 parts by mass of the total of the raw material monomer groups (m-X) and (m-Y) and the isocyanato group-containing ethylenically unsaturated compound (a), and ethyl acetate as a solvent so that the total concentration of the raw material monomer group (m-X), the RAFT agent and the radical polymerization initiator was 50 mass %. After the temperature was raised to 60° C., the reaction was carried out for 7 hours.

### Step i-2

Subsequently, 78 mol of n-butyl acrylate, 0.0160 parts by mass of 2,2′-azobis(2,4-dimethylvaleronitrile) per 100 parts by mass of the total of the raw material monomer groups (m-X) and (m-Y) and the isocyanato group-containing ethylenically unsaturated compound (a), and ethyl acetate as a solvent were charged so that the total concentration of the copolymer obtained in step (i-1), the raw material monomer group (m-Y) and the radical polymerization initiator added in step (i-2) was 50 mass %. After the temperature was raised to 60° C., the reaction was carried out for 14 hours.

### Step ii

Next, the reaction product was cooled to room temperature and diluted with ethyl acetate so that the concentration of the copolymer obtained in step (i-2) was 40 mass %. Next, the temperature of the diluted reaction product was raised to 55° C., and a mixed liquid of 13 mol of 2-isocyanatoethyl methacrylate and dibutyltin dilaurate as a urethane formation catalyst was added dropwise through the dropping funnel. The amount of dibutyltin dilaurate blended was 0.06 parts by mass per 100 parts by mass of the total of the copolymer obtained in step (i-2) and the isocyanato group-containing ethylenically unsaturated compound (a). After completion of the dropwise addition, the reaction system was retained at 60° C. for 4 hours to eliminate the isocyanate group. Thus, a liquid containing an X—Y—X type (meth)acrylic resin (cA1) having a weight average molecular weight of 300,000, a molecular weight distribution of 2.4, an ethylenically unsaturated group equivalent of 1109 g/mol, and a hydroxyl value of 11.46 mgKOH/g and having a solids content of 40 mass % was obtained.

### Comparative Synthesis Example 2

An X—Y—X type (meth)acrylic resin (cA2) was obtained in the same manner as in Comparative Synthesis Example 1 except that the composition shown in Table 1 was used.

### Comparative Synthesis Example 3

### Step i-1

A reaction device equipped with a stirrer, a temperature controller, a reflux condenser, a dropping funnel, and a thermometer was charged with 18 mol of styrene, 10 mol of 2-hydroxyethyl acrylate, 0.156 parts by mass of 4-cyano-4-[(dodecylsulfanylthiocarbonyl) sulfanyl]pentanoic acid per 100 parts by mass of the total of the raw material monomer groups (m-X) and (m-Y) and the isocyanato group-containing ethylenically unsaturated compound (a), 0.0405 parts by mass of 2,2′-azobis(2,4-dimethylvaleronitrile) per 100 parts by mass of the total of the raw material monomer groups (m-X) and (m-Y) and the isocyanato group-containing ethylenically unsaturated compound (a), and butyl acetate as a solvent so that the total concentration of the raw material monomer group (m-X), the RAFT agent and the radical polymerization initiator was 80 mass %. After the temperature was raised to 120° C., the reaction was carried out for 14 hours.

### Step i-2

Subsequently, 62 mol of n-butyl acrylate, 10 mol of 2-hydroxyethyl acrylate, 0.0405 parts by mass of 2,2′-azobis(2,4-dimethylvaleronitrile) per 100 parts by mass of the total of the raw material monomer groups (m-X) and (m-Y) and the isocyanato group-containing ethylenically unsaturated compound (a), and butyl acetate as a solvent were charged so that the total concentration of the copolymer obtained in step (i-1), the raw material monomer group (m-Y), and the radical polymerization initiator added in step (i-2) was 80 mass %. After the temperature was raised to 120° C., the reaction was carried out for 14 hours.

### Step ii

Next, the reaction product was cooled to room temperature and diluted with butyl acetate so that the concentration of the copolymer obtained in step (i-2) was 40 mass %. Next, the temperature of the diluted reaction product was raised to 55° C., and a mixed liquid of 18 mol of 2-isocyanatoethyl acrylate and dibutyltin dilaurate as a urethane formation catalyst was added dropwise through the dropping funnel. The amount of dibutyltin dilaurate blended was 0.06 parts by mass per 100 parts by mass of the total of the copolymer obtained in step (i-2) and the isocyanato group-containing ethylenically unsaturated compound (a). After completion of the dropwise addition, the reaction system was retained at 60° C. for 4 hours to eliminate the isocyanate group. Thus, a liquid containing a (meth)acrylic resin (cA3) having a weight average molecular weight of 250,000, a molecular weight distribution of 2.4, an ethylenically unsaturated group equivalent of 833 g/mol, and a hydroxyl value of 9.41 mgKOH/g and having a solids content of 40 mass % was obtained.

### Comparative Synthesis Example 4

### Step i-1

A reaction vessel was charged with 63 mol of n-butyl acrylate, 17 mol of 2-hydroxyethyl acrylate, 20 mol of isostearyl acrylate, 0.135 parts by mass of benzyldodecyl trithiocarbonate per 100 parts by mass of the total of the raw material monomer group (m-X) and the isocyanato group-containing ethylenically unsaturated compound (a), 0.0563 parts by mass of 2,2′-azobis (isobutyronitrile) per 100 parts by mass of the total of the raw material monomer group (m-X) and the isocyanato group-containing ethylenically unsaturated compound (a), and butyl acetate as a solvent so that the total concentration of the raw material monomer group (m-X), the RAFT agent and the radical polymerization initiator was 80 mass %. After the temperature was raised to 120° C., the reaction was carried out for 14 hours.

### Step ii

Next, the reaction product was cooled to room temperature and diluted with butyl acetate so that the concentration of the copolymer obtained in step (i-1) was 40 mass %. Next, the temperature of the diluted reaction product was raised to 55° C., and a mixed liquid of 15 mol of 2-isocyanatoethyl acrylate and dibutyltin dilaurate as a urethane formation catalyst was added dropwise through the dropping funnel. The amount of dibutyltin dilaurate blended was 0.06 parts by mass per 100 parts by mass of the total of the copolymer obtained in step (i-1) and the isocyanato group-containing ethylenically unsaturated compound (a). After completion of the dropwise addition, the reaction system was retained at 60° C. for 4 hours to eliminate the isocyanate group. Thus, a liquid containing a (meth)acrylic resin (cA4) having a weight average molecular weight of 280,000, a molecular weight distribution of 2.1, an ethylenically unsaturated group equivalent of 1221 g/mol, and a hydroxyl value of 5.04 mgKOH/g and having a solids content of 40 mass % was obtained.

### Comparative Synthesis Example 5

### Step i-1

A reaction vessel was charged with butyl acetate as a solvent so that the total concentration of the raw material monomer group (m-X) and the radical polymerization initiator was 60 mass %. A mixed liquid was prepared by mixing 63 mol of n-butyl acrylate, 17 mol of 2-hydroxyethyl acrylate, 20 mol of isostearyl acrylate, and 0.297 parts by mass of 2,2′-azobis(isobutyronitrile) per 100 parts by mass of the total of the raw material monomer group (m-X) and the isocyanato group-containing ethylenically unsaturated compound (a). After the temperature of butyl acetate in the reaction vessel was raised to 80° C., the mixed liquid was added dropwise over 3 hours. After completion of the dropwise addition, the reaction was continued at 80° C. for 4 hours.

### Step ii

Next, the reaction product was cooled to room temperature and diluted with butyl acetate so that the concentration of the copolymer obtained in step (i-1) was 40 mass %. Next, the temperature of the diluted reaction product was raised to 55° C., and a mixed liquid of 15 mol of 2-isocyanatoethyl acrylate and dibutyltin dilaurate as a urethane formation catalyst was added dropwise through the dropping funnel. The amount of dibutyltin dilaurate blended was 0.06 parts by mass per 100 parts by mass of the total of the copolymer obtained in step (i-1) and the isocyanato group-containing ethylenically unsaturated compound (a). After completion of the dropwise addition, the reaction system was retained at 60° C. for 4 hours to eliminate the isocyanate group. Thus, a liquid containing a (meth)acrylic resin (cA5) having a weight average molecular weight of 320,000, a molecular weight distribution of 4.2, an ethylenically unsaturated group equivalent of 1221 g/mol, and a hydroxyl value of 5.04 mgKOH/g and having a solids content of 40 mass % was obtained.

TABLE 1

| | | | | | Syn- | Syn- | Syn- | Syn- |
|---|---|---|---|---|---|---|---|---|
| | | | | | thesis | thesis | thesis | thesis |
| | | | | | Ex- | Ex- | Ex- | Ex- |
| | | | | | am- | am- | am- | am- |
| | | | | | ple | ple | ple | ple |
| | | | | | 1 | 2 | 3 | 4 |
| | | | | Unit | A1 | A2 | A3 | A4 |
| Step (i-1) | Raw material | m-1 | 2-Hydroxyethyl | mol | 17 | 18 | 2 | 15 |
| | monomer | | acrylate (23.1) | | | | | |
| | group | m-2 | Isopropenyl | | — | — | 13 | — |
| | (m-X) [symbol] | | methacrylate (17.0) | | | | | |
| | | Others | n-Butyl | | 58 | 60 | 66 | 26 |
| | | | acrylate (19.0) | | | | | |
| | | | Styrene (18.3) | | — | — | — | — |
| | | | Cyclohexyl | | — | — | — | 37 |
| | | | acrylate (18.0) | | | | | |
| | | | Esostearyl | | — | — | — | — |
| | | | acrylate (16.1) | | | | | |
| | Radical polymerization | | 2,2′-Azohis(N-butyl- | parts by mass | 0.0417 | — | 0.0342 | 0.375 |
| | initiator | | 2-methylpropionamide) | [symbol] | | | | |
| | | | 2,2 Axchiy(2,4- | | — | 0.0405 | — | — |
| | | | dimethylvalcronitrile) | | | | | |
| | | | 2,2′-Azobis | | — | — | — | — |
| | | | (isobutyronitrile) | | | | | |
| Step (i-2) | Raw material | m-3 | Styrene (18.3) | mol | 25 | — | 19 | 22 |
| | monomer | | isostearyl | | | | | |
| | group (m-Y) *¹ | | acrylate (16. 1) | | — | — | — | — |
| | | | n-Butyl acrylate (19.0) | | — | — | — | — |
| | | | Methyl | | — | — | — | — |
| | | | acrylate (18.8) | | | | | |
| | | | Methyl | | — | 22 | — | — |
| | | | methacrylate (18.0) | | | | | |
| | | m-1 | 2-Hydroxycthyl | | — | — | — | — |
| | | | acrylatc (23.1) | | | | | |

| | | | | | | |
|---|---|---|---|---|---|---|
| Radical polymerization | 2,2′-Azobis(N-buryl- | parts | 0.0417 | — | 0.0342 | 0.375 |
| initiator | 2-methylpropionumide) | by mass [symbol] # | | | | |

| | 2,2′-Azobis(2,4- | | — | 0.0405 | — | — |
|---|---|---|---|---|---|---|
| | dimethylvaleronitrile) | | | | | |
| | 2,2′-Axobis | | — | — | — | — |
| | (isobutyronitrile) | | | | | |
| Chain transfer agent | Benzyldodecyl | parts | 0.118 | — | 0.0957 | 0.498 |
| (RAFI agon) | trithicarbonate | by mass | | | | |
| | 4-Cyano-1-4[ | | — | 0.156 | — | — |
| | (dodecylsilfanylhocarbonyl) | | | | | |
| | sulfanyl] | | | | | |
| | pentaonic acid | | | | | |
| | Trithiocarbonic | | — | — | — | — |
| | acid bis[[ | | | | | |
| | 4-[[ethyl-(2- | | | | | |
| | acetoxyethyl) | | | | | |
| | amino)carbonyl] | | | | | |
| | phenyl] | | | | | |
| | methyl]ester | | | | | |
| | 2-Cyano-2- | | — | — | — | — |
| | propyldodecyl | | | | | |
| | trithiocarbonate | | | | | |
| Isocyanate group-containing | AO [symbol] VM | mol | 16 | 17 | — | 13 |
| ethologically | Karen [symbol] MOI | | | | | |
| unsaturated compound (a) | | | — | — | — | — |
| | Addition rate | mol % | 92% | 93% | 0% | 87% |
| | (relative to | | | | | |
| | hydroxy group) | | | | | |

| Array of blocks | | X-Y | X-Y | X-Y | X-Y |
|---|---|---|---|---|---|
| | | type | type | type | type |
| Molas ratio between structural units (X block/Y block) | | 75/25 | 78/22 | 81/19 | 78/22 |
| Proportion of structural unit (M-1) | mol % | 1.7 | 1.6 | 25 | 25 |
| having hydroxy group in X block | | | | | |
| Proportion of structural unit (M-2) | mol % | 21.0 | 21.4 | 36.0 | 16.7 |
| having ethylenically unsaturated group in X block | | | | | |
| Proportion of structural unit (M-3) | mol % | 10039 | 100.0 | 100.0 | 100.0 |
| derived from compound (m-3) in Y block | | | | | |
| Mw/Mn | | 2.6 | 2.3 | 3.0 | 2.1 |
| Mw | | 300,000 | 250,000 | 400,000 | 50,000 |
| Ethylenically unsaturated group equivalent | g/mol | 905 | 858 | 975 | 3143 |
| Hydroxyl value | mgKOH/g | 5.05 | 5.05 | 8.85 | 7.34 |

| | | | | | Syn- | Syn- | Syn- |
|---|---|---|---|---|---|---|---|
| | | | | | thesis | thesis | thesis |
| | | | | | Ex- | Ex- | Ex- |
| | | | | | am- | am- | am- |
| | | | | | ple | ple | ple |
| | | | | | 5 | 6 | 7 |
| | | | | Unit | A5 | A6 | A7 |
| Step (i-1) | Raw material | m-1 | 2-Hydroxyethyl | mol | 16 | 15 | 17 |
| | monomer | | acrylate (23.1) | | | | |
| | group | m-2 | Isopropenyl | | — | — | — |
| | (m-X) [symbol] | | methacrylate (17.0) | | | | |
| | | Others | n-Butyl | | 18 | 57 | 58 |
| | | | acrylate (19.0) | | | | |
| | | | Styrene (18.3) | | — | — | — |
| | | | Cyclohexyl | | 22 | — | — |
| | | | acrylate (18.0) | | | | |
| | | | Esostearyl | | — | — | — |
| | | | acrylate (16.1) | | | | |
| | Radical polymerization | | 2,2′-Azohis(N-butyl- | parts by mass | 0.0107 | — | — |
| | initiator | | 2-methylpropionamide) | [symbol] | | | |
| | | | 2,2 Axchiy(2,4- | | — | 0.0410 | 0.0563 |
| | | | dimethylvalcronitrile) | | | | |
| | | | 2,2′-Azobis | | — | — | — |
| | | | (isobutyronitrile) | | | | |
| Step (i-2) | Raw material | m-3 | Styrene (18.3) | mol | 44 | 26 | — |
| | monomer | | isostearyl | | | | |
| | group (m-Y) *¹ | | acrylate (16. 1) | | — | — | 20 |
| | | | n-Butyl acrylate (19.0) | | — | — | 5 |
| | | | Methyl | | — | — | — |
| | | | acrylate (18.8) | | | | |
| | | | Methyl | | — | — | — |
| | | | methacrylate (18.0) | | | | |
| | | m-1 | 2-Hydroxycthyl | | — | 2 | — |
| | | | acrylatc (23.1) | | | | |

| | | | | | |
|---|---|---|---|---|---|
| Radical polymerization | 2,2′-Azobis(N-buryl- | parts | — | — | — |
| initiator | 2-methylpropionumide) | by mass [symbol] # | | | |

| | 2,2′-Azobis(2,4- | | 0.0107 | 0.0410 | — |
|---|---|---|---|---|---|
| | dimethylvaleronitrile) | | | | |
| | 2,2′-Axobis | | — | — | 0.0563 |
| | (isobutyronitrile) | | | | |
| Chain transfer agent | Benzyldodecyl | parts | — | — | 0.135 |
| (RAFI agon) | trithicarbonate | by mass | | | |
| | 4-Cyano-1-4 | | 0.0296 | 0.156 | — |
| | [(dodecylsilfanylhocarbonyl) | | | | |
| | sulfanyl] | | | | |
| | pentaonic acid | | | | |
| | Trithiocarbonic | | — | — | — |
| | acid bis[[ | | | | |
| | 4-[[ethyl-(2- | | | | |
| | acetoxyethyl) | | | | |
| | amino)carbonyl] | | | | |
| | phenyl] | | | | |
| | methyl]ester | | | | |
| | 2-Cyano-2- | | — | — | — |
| | propyldodecyl | | | | |
| | trithiocarbonate | | | | |
| Isocyanate group-containing | AO [symbol] VM | mol | 14 | 15 | 15 |
| ethologically | Karen [symbol] MOI | | | | |
| unsaturated compound (a) | | | — | — | — |

| | | | | |
|---|---|---|---|---|
| Addition rate | mol % | 80% | 91% | 90% |
| (relative to | | | | |
| hydroxy group) | | | | |

| Array of blocks | | X-Y | X-Y | X-Y |
|---|---|---|---|---|
| | | type | type | type |
| Molas ratio between structural units (X block/Y block) | | 56/44 | 72/28 | 75/25 |
| Proportion of structural unit (M-1) | mol % | 3.9 | 1.9 | 2.2 |
| having hydroxy group in X block | | | | |
| Proportion of structural unit (M-2) | mol % | 24.7 | 18.9 | 26.4 |
| having ethylenically unsaturated group in X block | | | | |
| Proportion of structural unit (M-3) | mol % | 100.0 | 92.9 | 100.0 |
| derived from compound (m-3) in Y block | | | | |
| Mw/Mn | | 2.8 | 2.6 | 2.9 |
| Mw | | 900,000 | 250,000 | 280,000 |
| Ethylenically unsaturated group equivalent | g/mol | 1020 | 917 | 1221 |
| Hydroxyl value | mgKOH/g | 8.68 | 6.44 | 5.04 |

| | | | | | Compar- | Compar- | Compar- | Compar- |
|---|---|---|---|---|---|---|---|---|
| | | | | | ative | ative | ative | ative |
| | | | | | Syn- | Syn- | Syn- | Syn- |
| | | | | | thesis | thesis | thesis | thesis |
| | | | | | Example 1 | Example 2 | Example 3 | Example 4 |
| | | | | Unit | cA1 | cA2 | cA3 | cA4 |
| Step | Raw material | m-1 | 2-Hydroxyethyl | mol | 16 | 15 | 10 | 17 |
| (i-1) | monomer | | acrylate (23.1) | | | | | |
| | group | m-2 | Isopropyl | | — | — | — | — |
| | | | methacrylate (17.0) | | | | | |
| | (m-X) *¹ | Others | n-Butyl | | 6 | — | — | 63 |
| | | | acrylate (19.0) | | | | | |
| | | | Styrene (18.3) | | — | — | 18 | — |
| | | | Cyclohexyl | | — | — | — | — |
| | | | acrylate (18.0) | | | | | |
| | | | Isostcaryl acrylate (16.1) | | — | — | — | 20 |
| | Radical | | 2,2′-Azobis(N- | parts by | — | — | — | — |
| | | | butyl-2- | | | | | |
| | | | methylpropionandde) | | | | | |
| | polymerization | | 2,2′-Azobis | mass * [symbol] | 0.0160 | — | 0.0405 | — |
| | | | (2,4-dimethylvaloronitrile) | | | | | |
| | initiator | | 2,2′-Azobis | | — | 0.0304 | — | 0.0563 |
| | | | (isobutyronitrile) | | | | | |
| Step | Raw material | m-3 | Styrene (18.3) | mol | — | — | — | — |
| | monomer | | | | | | | |
| (i-2) | group (m-Y) *1 | | Isostcaryl acrylate (16.1) | | — | — | — | — |
| | | | n-Butyl acrylate (19.0) | | 75 | 64 | 62 | — |
| | | | Methyl acrylate (18.8) | | — | 21 | — | — |
| | | | Methyl methacrylate (18.0) | | — | — | — | — |
| | | m-1 | 2-Hydroxyethyl | | — | — | 10 | — |
| | | | acrylate (23.1) | | | | | |

| | | | | | | |
|---|---|---|---|---|---|---|
| Radical | 2,2′Azobis(N-butyl- | parts by | — | — | — | — |
| polymerization | 2-methylpropionamide) | mass * [symbol] | | | | |
| initiator | 2,2′-Azobis | | 0.0160 | — | 0.0405 | — |
| | (2,4-dimethylvaloronitrile) | | | | | |

| | 2,2′-Azbis(isobutyrosigile) | | — | 0.0301 | — | — |
|---|---|---|---|---|---|---|
| Chain transfer agent | Benzyldodecyl | parts by | — | — | — | 0.135 |
| | trillecarbonate | | | | | |
| (RAFT agent) | 4-Cyano-4- | mass * [symbol] | — | — | 0.156 | — |
| | ((dodecylsulfanylthiocarbonyl) | | | | | |
| | sulfanyl] | | | | | |
| | pentanoic acid | | | | | |
| | Trithiocarbonic acid | | 0.260 | 0.320 | — | — |
| | bis[[4-[[ethyl- | | | | | |
| | (2-acetoxyethyl)amino | | | | | |
| | ]carbonyl]phenyl | | | | | |
| | [methyl]ester | | | | | |
| | 2-Cyano-2-propridodecyl | | — | — | — | — |
| | trithiccarbonate | | | | | |
| Isocyanate group-containing | AOI-VM | mol | — | — | 18 | 15 |
| chrylenically unsaturated | Karenz MOI | | 13 | 11 | — | — |
| compound (a) | Addition rate | mol % | 82% | 76% | 90% | 90% |
| | (relative to | | | | | |
| | hydroxy group) | | | | | |

| Any of blocks | | X-Y-X | X-Y-X | X-Y | — |
|---|---|---|---|---|---|
| | | type | type | type | |
| Molar ratio between suuchwal | | | 15/85 | 28/72 | — |
| units (X block/Y block) 22/78 | | | | | |
| Proportion of structural unit (M-1) | mol % | 13.4 | 13.6 | 3.6 | 2.1 |
| having hydroxy group in X block. | | | | | |
| Proportion of structural unit (M-2) | mol % | 59.3 | 76.0 | 32.1 | 15.3 |
| having cuhry lenically unsaturated group in X block | | | | | |
| Proportion of structural unit (M-3) | mol % | 100.0 | 1000 | 86.9 | — |
| derived from compound (m-3) in Y block | | | | | |
| Mw/Mn | | 2.4 | 1.5 | 2.4 | 2.1 |
| Mw | | 300,000 | 200,000 | 250,000 | 280,000 |
| Ethylemcally wsaturated group opuvalent | g/mol | 1109 | 1172 | 833 | 1221 |
| Hydroxyl vaive | mg/KOH/g | 11.46 | 15.09 | 9.41 | 5.04 |

| | | | | | Compar- |
|---|---|---|---|---|---|
| | | | | | ative |
| | | | | | Syn- |
| | | | | | thesis |
| | | | | | Example 5 |
| | | | | Unit | cA5 |
| Step | Raw material | m-1 | 2-Hydroxyethyl | mol | 17 |
| (i-1) | monomer | | acrylate (23.1) | | |
| | group | m-2 | Isopropyl | | — |
| | | | methacrylate (17.0) | | |
| | (m-X) *¹ | Others | n-Butyl | | 63 |
| | | | acrylate (19.0) | | |
| | | | Styrene (18.3) | | — |
| | | | Cyclohexyl | | — |
| | | | acrylate (18.0) | | |
| | | | Isostcaryl acrylate (16.1) | | 20 |
| | Radical | | 2,2′-Azobis(N- | parts by | — |
| | | | butyl-2- | | |
| | | | methylpropionandde) | | |
| | polymerization | | 2,2′-Azobis | mass * [symbol] | — |
| | | | (2,4-dimethylvaloronitrile) | | |
| | initiator | | 2,2′-Azobis | | 0.297 |
| | | | (isobutyronitrile) | | |
| Step | Raw material | m-3 | Styrene (18.3) | mol | — |
| | monomer | | | | |
| (i-2) | group (m-Y) *1 | | Isostcaryl acrylate (16.1) | | — |
| | | | n-Butyl acrylate (19.0) | | — |
| | | | Methyl acrylate (18.8) | | — |
| | | | Methyl methacrylate (18.0) | | — |
| | | m-1 | 2-Hydroxyethyl | | — |
| | | | acrylate (23.1) | | |

| | | | |
|---|---|---|---|
| Radical | 2,2′Azobis(N-butyl- | parts by | — |
| polymerization | 2-methylpropionamide) | mass * [symbol] | |
| initiator | 2,2′-Azobis | | — |
| | (2,4-dimethylvaloronitrile) | | |

| | 2,2′-Azbis(isobutyrosigile) | | — |
|---|---|---|---|
| Chain transfer agent | Benzyldodecyl | parts by | — |
| | trillecarbonate | | |
| (RAFT agent) | 4-Cyano-4- | mass * [symbol] | — |
| | ((dodecylsulfanylthiocarbonyl) | | |
| | sulfanyl] | | |
| | pentanoic acid | | |
| | Trithiocarbonic acid | | — |
| | bis[[4-[[ethyl- | | |
| | (2-acetoxyethyl)amino | | |
| | ]carbonyl]phenyl | | |
| | [methyl]ester | | |
| | 2-Cyano-2-propridodecyl | | — |
| | trithiccarbonate | | |
| Isocyanate group-containing | AOI-VM | mol | 15 |
| chrylenically unsaturated | Karenz MOI | | — |
| compound (a) | Addition rate | mol % | 90% |
| | (relative to | | |
| | hydroxy group) | | |

| Any of blocks | | — |
|---|---|---|
| Molar ratio between suuchwal | mol % | 2.1 |
| units (X block/Y block) 22/78 | | |
| Proportion of structural unit (M-1) | | |
| having hydroxy group in X block. | | |
| Proportion of structural unit (M-2) | mol % | 15.3 |
| having cuhry lenically unsaturated group in X block | | |
| Proportion of structural unit (M-3) | mol % | — |
| derived from compound (m-3) in Y block | | |
| Mw/Mn | | 4.2 |
| Mw | | 320,000 |
| Ethylemcally wsaturated group opuvalent | g/mol | 1221 |
| Hydroxyl vaive | mg/KOH/g | 5.04 |

*¹ The number in parentheses is the SP value of the monomer.
*² Parts by mass per 100 parts by mass of the total of the raw material monomer groups (in-X) and (in-Y) and the isocyanate group-containing ethylenically unsaturated compound (a) [symbol]
indicates data missing or illegible when filed

Raw materials used for preparation of pressure-sensitive adhesive compositions are shown below.

### Photopolymerization Initiator (B):

TPO: 2,4,6-Trimethylbenzoyldiphenylphosphine oxide (BASF, trade name: L-TPO)
Irgacure 500: A mixture of 1-hydroxycyclohexyl phenyl ketone and benzophenone (BASF, trade name: Irgacure 500)
Crosslinking agent (C)
Takenate: Tolylene diisocyanate adduct of trimethylolpropane (Mitsui Chemicals, Inc., trade name: Takenate D-101E)
L-55E: Tolylene diisocyanate adduct of trimethylolpropane (Tosoh Corporation, trade name: Coronate L-55E)
L-45E: Tolylene diisocyanate adduct of trimethylolpropane (Tosoh Corporation, trade name: Coronate L-45E)

### [Preparation of Pressure-Sensitive Adhesive Composition]

Ethyl acetates as diluting solvents were added to the liquids containing the (meth)acrylic resins (A1) to (A7) and (cA1) to (cA5) obtained in Synthesis Examples 1 to 7 and Comparative Synthesis Examples 1 to 5 to adjust the content of each of the (meth)acrylic resins (A1) to (A7) and (cA1) to (cA5) to 30 mass %. Using the liquid, a pressure-sensitive adhesive composition was obtained by the following method.

In a room shielded from active rays, the (meth)acrylic resins (A) or (cA), the photopolymerization initiator (B), and the crosslinking agent (C) shown in Table 2 were added to plastic containers in the contents (parts by mass) shown in Table 2 and stirred to obtain pressure-sensitive adhesive compositions (B1) to (B7) and (cB1) to (cB5).

### [Example 1] Preparation of Pressure-Sensitive Adhesive Sheet

As a release sheet, a silicone-based easy-release PET film (Toyobo Co., Ltd., product name: E7006, 25 μm thick) was prepared, and the pressure-sensitive adhesive composition (B1) was applied to the release-treated surface to attain a thickness of 11 μm after thermal curing, and heat-dried at 110° C. for 2 minutes to form a pressure-sensitive adhesive composition layer. Next, a PO film having a thickness of 90 μm was prepared as a sheet-shaped base material. The PO film was attached to the pressure-sensitive adhesive composition layer using a rubber roller so that the corona-treated surface of the PO film adhered to the exposed surface of the pressure-sensitive adhesive composition layer. The resultant product was cured in an oven at 40° C. for 3 days to crosslink and set the pressure-sensitive adhesive composition layer, thereby obtaining a pressure-sensitive adhesive sheet of Example 1.

### [Examples 2 to 7 and Comparative Examples 1 to 5] Preparation of Pressure-Sensitive Adhesive Sheet

Pressure-sensitive adhesive sheets of Examples 2 to 7 and Comparative Examples 1 to 5 were obtained in the same manner as in Example 1 except that the pressure-sensitive adhesive compositions (B2) to (B7) and (cB1) to (cB5) were used instead of the pressure-sensitive adhesive composition (B1) and that the thicknesses of the pressure-sensitive adhesive composition layers after thermal curing were as shown in Table 2.

### [Pressure-Sensitive Adhesiveness Evaluation]

### (1) Measurement of Initial Pressure-Sensitive Adhesive Strength (180° Peel Strength)

As described below, the pressure-sensitive adhesive strength of the pressure-sensitive adhesive sheets according to Examples and Comparative Examples to a wafer was evaluated by measuring the 180° peel strength. Samples having a width of 25 mm and a length of 100 mm were cut out from the pressure-sensitive adhesive sheets of Examples 1 to 7 and Comparative Examples 1 to 5. The silicone-based easy-release PET film was peeled off to expose the pressure-sensitive adhesive layer, and the pressure-sensitive adhesive layer was bonded to a test dummy wafer (AS ONE Corporation) with a rubber roller. Pressure bonding was performed using an autoclave (TAC-200, Sakura Seiki Co., Ltd.) to obtain a sample for pressure-sensitive adhesive strength measurement. The peel strength of the pressure-sensitive adhesive sheet to the wafer was measured using a tensile tester (Stable Micro Systems, TAXT2i) and determined as the initial pressure-sensitive adhesive strength. The measurement conditions were a peel angle of 180° and a tensile speed of 5 mm/sec. The storage of the sample and the measurement of the peel strength were performed in an environment at a temperature of 23° C. and a relative humidity of 40%. The results are shown in Table 2.

### (2) Measurement of Post-Immersion Pressure-Sensitive Adhesive Strength (180° Peel Strength)

A sample for pressure-sensitive adhesive strength measurement was prepared in the same manner as in (1) Measurement of initial pressure-sensitive adhesive strength (180° peel strength). The obtained measurement sample was immersed in ion-exchanged water, and allowed to stand for 3 hours in an environment of a temperature of 23° C. and a humidity of 40%. After the immersion treatment, the sample was taken out and excess water was removed, and then the peel strength of the pressure-sensitive adhesive sheet to the wafer was measured in the same manner as in (1) Measurement of initial pressure-sensitive adhesive strength (180° peel strength), and determined as the post-immersion pressure-sensitive adhesive strength. From the measurement results, the pressure-sensitive adhesive strength change rate was calculated using the following equation. The results are shown in Table 2.

$$\text{Pressure-sensitive adhesive strength change rate} ( \% ) = ( ( \text{post-immersion pressure-sensitive adhesive strength} ) - ( \text{initial pressure-sensitive adhesive strength} ) / ( \text{initial pressure-sensitive adhesive strength} ) ) \times 100$$

### (3) Measurement of Post-UV Irradiation Pressure-Sensitive Adhesive Strength (30° Peel Strength)

A sample for pressure-sensitive adhesive strength measurement was prepared in the same manner as in (1) Measurement of initial pressure-sensitive adhesive strength (180° peel strength). Ultraviolet rays (UV) were applied, at an irradiation amount of 300 mJ/cm², from the surface, on the side of the base material, of the pressure-sensitive adhesive sheet to afford a measurement sample for post-UV irradiation pressure-sensitive adhesive strength measurement. A conveyor type ultraviolet irradiation device (EYE GRAPHICS COMPANY, 2 KW lamp, 80 W/cm) was used for UV irradiation. Thereafter, the peel strength of the pressure-sensitive adhesive sheet to the wafer was measured in the same manner as in (1) Measurement of initial pressure-sensitive adhesive strength (180° peel strength), except that the peel angle was changed to 30°, and determined as the post-UV irradiation pressure-sensitive adhesive strength. The results are shown in Table 2.

TABLE 2

| | | | Ex- | Ex- | Ex- | Ex- |
|---|---|---|---|---|---|---|
| | | Unit | ample 1 | ample 2 | ample 3 | ample 4 |
| (Meth)acrylic resin (A) or (cA) | | | A1 | A2 | A3 | AA |
| Photo- | TPO | parts by mass *¹ | 0.5 | 0.75 | 0.75 | 1.8 |
| polymerization | Irgacure 508 | | — | — | — | — |
| initiator (B) | | | | | | |
| Crosslinking | Takemate | parts by mass *¹ | 0.2 | 04 | 0.1 | 0.2 |
| agent (C) | L-55E | | — | — | — | — |
| | L-45E | | — | — | — | — |

| Base material | | | 90 μm PO | 90 μm PO | 90 μm PO |
|---|---|---|---|---|---|
| Film thickness | μm | 11 | 9 | 9 | 8 |
| Initial pressure-sensitive adhesive strength | N/25 mm | 15.1 | 7.8 | 8.5 | 5.8 |
| Post-immersion pressure-sensitive adhesive strength | N/25 mm | 14.9 | 7.2 | 7.8 | 5.6 |
| Pressure-sensitive adhesive strength change rate | % | −1% | −8% | −8% | −3% |
| Post-UV irradiation pressure sensitive adhesive strength | N/25 mm | 0.05 | 0.09 | 010 | 0.01 |

| | | | | |
|---|---|---|---|---|
| Blade dicing test | S | A | A | B |
| Pickup test | S | B | A | S |

| | | | Ex- | Ex- | Ex- |
|---|---|---|---|---|---|
| | | Unit | ample 5 | ample 6 | ample 7 |
| (Meth)acrylic resin (A) or (cA) | | | A5 | A6 | A7 |
| Photo- | TPO | parts by mass *¹ | 0.5 | 0.3 | 05 |
| polymerization | Irgacure 508 | | — | — | — |
| initiator (B) | | | | | |
| Crosslinking | Takemate | parts by mass *¹ | 1.2 | 1.0 | 02 |
| agent (C) | L-55E | | — | — | — |
| | L-45E | | — | — | — |

| Base material | | 90 μm PO | 90 μm PO | 90 μm PO |
|---|---|---|---|---|
| Film thickness | μm | 9 | 9 | 10 |
| Initial pressure-sensitive adhesive strength | N/25 mm | 86 | 10.1 | 10.2 |
| Post-immersion pressure-sensitive adhesive strength | N/25 mm | 8.5 | 9.0 | 9.2 |
| Pressure-sensitive adhesive strength change rate | % | −1% | −11% | −30% |
| Post-UV irradiation pressure sensitive adhesive strength | N/25 mm | 0.02 | 0.01 | 0.01 |

| | | | |
|---|---|---|---|
| Blade dicing test | S | A | S |
| Pickup test | S | S | S |

| | | | Compar- | Compar- | Compar- | Compar- | Compar- |
|---|---|---|---|---|---|---|---|
| | | | ative | ative | ative | ative | ative |
| | | Unit | Example 1 | Example 2 | Example 3 | Example 4 | Example 5 |
| (Merhiacrylic resia (A) or (cA) | | | cA1 | cA2 | cA3 | cA4 | cA5 |
| Photopolymerization | TPO | parts by mass*1 | — | — | 0.3 | — | 8.5 |
| initiator (B) | Irgacure 500 | | 1.5 | 10.7 | — | — | — |
| Crosslinking | Takemate | parts by mass *1 | — | — | 1.0 | 0.2 | 0.2 |
| agent (C) | | | 0.5 | — | — | — | — |
| | L-55E | | — | 2.1 | — | — | — |
| | L-45E | | | | | | |

| Base material | | 90 μm PO | 90 μm PO | 90 μm PO | 90 μm PO | 90 μm PO |
|---|---|---|---|---|---|---|
| Film thickness | μm | 9 | 10 | 10 | 9 | 10 |
| Initial pressure-sensitive adhesive switch | N/25 mm | 9.6 | 4.5 | 4.2 | 14.5 | 15.2 |
| Post-immersion pressure-sensitive adhesive strength | N/25 mm | 2.0 | 1.0 | 1.2 | 6.5 | 3.2 |
| Pressure sensitive adhesive strength change rate | % | −79% | —78% | —71% | —55% | —79% |
| Post-UV irradiation pressure-sensitive adhesive strength | N/25 mm | 0.08 | 0.01 | 0.12 | 0.02 | 0.04 |

| | | | | | |
|---|---|---|---|---|---|
| Blade diving test | B | C | C | B | C |
| Pickup test | S | S | B | A | A |

*¹ Parts by mass per 100 parts by mass of the (meth)acrylic resin (A) or (cA)

### [Preparation of Dicing/Die Bonding Integrated Film]

A cover film on one surface of a die bonding film (FH-D25T-50, Resonac Corporation) in which both surfaces of the adhesive layer were protected by cover films was peeled off to expose the adhesive layer. This adhesive layer and the pressure-sensitive adhesive layer of each of the pressure-sensitive adhesive sheets of Examples 1 to 7 and Comparative Examples 1 to 5, from which the easy-release PET film had been peeled off to expose the pressure-sensitive adhesive layer, were bonded together with a rubber roller. The product was left at room temperature for 1 day to obtain a dicing/die bonding integrated film.

### [Processability Evaluation]

### (1) Blade Dicing Test (Dicing Properties)

Using the dicing/die bonding integrated film, dicing of a semiconductor wafer was performed in the following manner. Among the semiconductor chips (total number: 400) after dicing, the number of the semiconductor chips causing chip fly-off, that is, the semiconductor chips detached and scattered from the dicing/die bonding integrated film was counted, and a chip fly-off rate (%) was determined to evaluate the dicing properties. Therefore, the dicing properties are better as the chip fly-off rate is closer to 0%.

First, a semiconductor wafer (diameter: 8 inches, thickness: 0.6 mm; silicon mirror wafer) was subjected to a rear surface polishing treatment to obtain a 0.2 mm thick mirror wafer. Next, the mirror wafer was bonded by roll pressure bonding at 70° C. to the adhesive layer exposed by peeling off the cover film from the dicing/die bonding integrated film. Further, the mirror wafer was diced. The mirror wafer was full-cut to a chip size of 1.0 mm angle. The bonding conditions and dicing conditions are as follows.

### <Semiconductor Wafer Polishing Conditions>

Grinder: trade name DFG-8560 (DISCO Corporation)
Semiconductor wafer: 8 inch diameter (rear surface polished from 0.6 mm to 0.2 mm thick)

### <Bonding Conditions>

Attaching device: trade name MA-3000III (Nitto Seiki Co., Ltd.)
Attaching speed: 10 mm/min
Attaching pressure: 0.15 MPa
Stage temperature during attachment: 70° C.

### <Dicing Conditions>

Dicing device: trade name DFD-6361 (DISCO Corporation)
Dicing ring: 2-8-1 (DISCO Corporation)
Dicing speed: 30 mm/sec
Dicing blade: Z1; 2030-SE 27HCDD (DISCO Corporation)
   Z2; 2030-SE 27HCBB (DISCO Corporation)
Dicing blade rotation speed: Z1; 40,000 r/min
   Z2; 45,000 r/min
Cutting method: step cutting
Wafer chip size: 1.0 mm square
Cutting water supply amount: 2.0 L/min

### <Evaluation Criteria for Dicing Properties>

S: The chip fly-off rate was 0% or more and less than 5%.
A: The chip fly-off rate was 5% or more and less than 10%.
B: The chip fly-off rate was 10% or more and less than 20%.
C: The chip fly-off rate was 20% or more.

### (2) Pickup Test (Pickup Properties)

After dicing the mirror wafer as described above, the semiconductor chips were picked up. The pickup was performed after the pressure-sensitive adhesive layer was irradiated with ultraviolet rays. The irradiation conditions are as follows. After the ultraviolet irradiation, a semiconductor chip with an adhesive piece obtained by dicing was pushed up with a needle from the side of the dicing tape of the dicing/die bonding integrated film and picked up from the pressure-sensitive adhesive layer. At this time, a pickup success rate (%) of the semiconductor chips (total number: 400) was determined to evaluate the pickup properties. Therefore, the pickup properties are better as the pickup rate is closer to 100%. Chips that had flown off were not included in the population parameter. The pickup conditions are as follows.

### <Ultraviolet Irradiation Conditions>

Ultraviolet (UV) irradiation device: high-pressure mercury lamp
Integral light amount of ultraviolet irradiation: 500 mJ/cm²
Output: 75 W
Irradiation intensity: 150 mW/cm²

The ultraviolet irradiation was performed from the surface, on the side of the base material, of the dicing tape.

### <Pickup Conditions>

Pickup device: trade name SPA-300 (SHINKAWA LTD.)
Number of pickup needles: 1
Needle push-up speed: 20 mm/second
Needle push-up amount: 500 μm
Pickup time: 1 second
Dicing tape expanding amount: 3 mm

### <Evaluation Criteria>

S: The pickup success rate was 95% or more and 100% or less.
A: The pickup success rate was 80% or more and less than 95%.
B: The pickup success rate was 60% or more and less than 80%.
C: The pickup success rate was less than 60%.

The pressure-sensitive adhesive sheets according to Examples 1 to 7 had a small change rate in pressure-sensitive adhesive strength and excellent water resistance. The dicing/die bonding integrated films prepared by using the pressure-sensitive adhesive sheets according to Examples 1 to 7 had good results in both the blade dicing test and the pickup test.

### INDUSTRIAL APPLICABILITY

According to the present disclosure, there is provided a pressure-sensitive adhesive composition that provides a pressure-sensitive adhesive sheet having high pressure-sensitive adhesive strength and excellent water resistance to cutting water, and having significantly reduced pressure-sensitive adhesive strength upon ultraviolet irradiation. A pressure-sensitive adhesive layer formed from the pressure-sensitive adhesive composition can be preferably used as a removable pressure-sensitive adhesive sheet, particularly as a pressure-sensitive adhesive layer of a dicing tape.

1. A pressure-sensitive adhesive composition comprising:
a (meth)acrylic resin (A);
a photopolymerization initiator (B); and
a crosslinking agent (C), wherein
the (meth)acrylic resin (A) is a diblock copolymer composed of an X block and a Y block;
a structural unit ratio (molar ratio) between the X block and the Y block is from 40:60 to 95:5;
the X block includes:
a structural unit (M-1) having a hydroxy group, and
a structural unit (M-2) having an ethylenically unsaturated group;
the Y block includes:
a structural unit (M-3) derived from an ethylenically unsaturated compound (m-3) having an SP value of 20 (J/cm³)^{1/2} or less, and
optionally, one or more structural units selected from the group consisting of a structural unit (M-1) having a hydroxy group and a structural unit (M-2) having an ethylenically unsaturated group;
at least one of the structural unit (M-1), the structural unit (M-2), and the structural unit (M-3) has a structure derived from a (meth)acryloyloxy group;
a total amount of the structural unit (M-1) having a hydroxy group and the structural unit (M-2) having an ethylenically unsaturated group included in the X block is from 18 to 95 mol % relative to 100 mol % of a total of structural units in the X block; and
a total amount of the structural unit (M-1) having a hydroxy group and the structural unit (M-2) having an ethylenically unsaturated group included in the Y block is from 0 to 17 mol % relative to 100 mol % of a total of structural units in the Y block.

2. The pressure-sensitive adhesive composition according to claim 1, wherein an amount of the structural unit (M-2) having an ethylenically unsaturated group included in the X block is from 1 to 60 mol % relative to 100 mol % of the total of structural units in the X block.

3. The pressure-sensitive adhesive composition according to claim 1, wherein an amount of the structural unit (M-1) having a hydroxy group included in the X block is from 0.1 to 35 mol % relative to 100 mol % of the total of structural units in the X block.

4. The pressure-sensitive adhesive composition according to any of claim 1, wherein the structural unit (M-2) having an ethylenically unsaturated group included in the X block is a structural unit in which an isocyanato group-containing ethylenically unsaturated compound (a) is added to a hydroxy group of a structural unit derived from an ethylenically unsaturated compound (m-1) having a hydroxy group.

5. The pressure-sensitive adhesive composition according to claim 1, wherein an amount of the structural unit (M-3) derived from the ethylenically unsaturated compound (m-3) having an SP value of 20 (J/cm³)^{1/2} or less included in the Y block is 70 mol % or more relative to 100 mol % of the total of structural units in the Y block.

6. The pressure-sensitive adhesive composition according to claim 1, wherein the structural unit (M-3) derived from the ethylenically unsaturated compound (m-3) having an SP value of 20 (J/cm³)^{1/2} or less included in the Y block is a structural unit derived from a monomer selected from the group consisting of a linear or branched alkyl (meth)acrylate having an alkyl group with from 6 to 30 carbon atoms, an alicyclic skeleton-containing (meth)acrylate, and styrene.

7. The pressure-sensitive adhesive composition according to claim 1, wherein the Y block includes a structural unit derived from styrene.

8. The pressure-sensitive adhesive composition according to claim 1, wherein the X block further includes a structural unit derived from a linear or branched alkyl (meth)acrylate having an alkyl group with from 1 to 5 carbon atoms.

9. The pressure-sensitive adhesive composition according to claim 1, wherein the (meth)acrylic resin (A) has an weight average molecular weight of from 1×10⁴ to 200×10⁴.

10. The pressure-sensitive adhesive composition according to any of claim 1, wherein the (meth)acrylic resin (A) has an ethylenically unsaturated group equivalent of from 100 to 5000 g/mol.

11. The pressure-sensitive adhesive composition according to any of claim 1, wherein the (meth)acrylic resin (A) has a hydroxyl value of from 0.01 to 50 mgKOH/g.

12. A pressure-sensitive adhesive sheet including:
a base material layer; and
a pressure-sensitive adhesive layer composed of a thermally cured product or photothermally cured product of the pressure-sensitive adhesive composition described in claim 1.

13. A dicing tape including:
a base material layer; and
a pressure-sensitive adhesive layer composed of a thermally cured product or photothermally cured product of the pressure-sensitive adhesive composition described in claim 1.

14. A dicing/die bonding integrated film including:
a base material layer;
a pressure-sensitive adhesive layer composed of a thermally cured product or photothermally cured product of the pressure-sensitive adhesive composition described in claim 1; and
an adhesive layer in this order.
